(19) United States
(12) Patent Application Publication
(10) Pub. No.: US 2012/0170163 A1
(43) Pub. Date: Jul. 5, 2012

(54) BARRIER DIODE FOR INPUT POWER PROTECTION

(76) Inventor: Adrian Mikolajczak, Los Altos, CA (US)

(21) Appl. No.: 13/307,326

(22) Filed: Nov. 30, 2011

Related U.S. Application Data
(60) Provisional application No. 61/429,095, filed on Dec. 31, 2010.

(51) Int. Cl. H02H 9/02; H01L 29/87; H01L 29/861; H01L 27/06

(52) U.S. Cl. 361/57; 257/491; 257/109; 257/487; 257/E27.024; 257/E29.337; 257/E29.327

(57) ABSTRACT

In one general aspect, an apparatus can include a barrier diode including a refractory metal layer coupled to a semiconductor substrate including at least a portion of a PN junction and the apparatus can include an overcurrent protection device operably coupled to the barrier diode.

### RELATED APPLICATION

This application claims priority to and the benefit of U.S. Provisional Patent Application Ser. No. 61/429,095, filed on Dec. 31, 2010, entitled, “Barrier Diode for Input Power Protection,” which is incorporated herein by reference in its entirety.

### TECHNICAL FIELD

This description relates to an input power port protection component.

### BACKGROUND

Input power ports and/or related components can be protected from undesirable power conditions (e.g., overcurrent conditions and/or overvoltage conditions) using multiple discrete devices such as fuses and/or zener diodes (e.g., TVS diodes). When the input power port is protected from undesirable power conditions using multiple discrete devices, unpredictable and/or unwanted interactions can occur between the discrete devices. For example, certain discrete devices selected for overvoltage protection of the input power port may not interact in a favorable fashion with other discrete devices selected for overcurrent protection of the input power port. Unmatched components can result in various irregular failure modes and/or damage to downstream components intended for protection at the input power port. Also, the complexity and cost of assembly of protection at an input power port may be increased in an unfavorable manner when multiple discrete components are used in conventional circuits used for the input power port protection. Thus, a need exists for systems, methods, and apparatus to address the shortfalls of present technology and to provide other new and innovative features.

### SUMMARY

In one general aspect, an apparatus can include a barrier diode including a refractory metal layer coupled to a semiconductor substrate including at least a portion of a PN junction and the apparatus can include an overcurrent protection device operably coupled to the barrier diode.

The details of one or more implementations are set forth in the accompanying drawings and the description below. Other features will be apparent from the description and drawings, and from the claims.

### BRIEF DESCRIPTION OF THE DRAWINGS

FIG. 1A is a diagram that illustrates a barrier diode, according to an embodiment.

FIG. 1B is a graph that illustrates a current versus voltage (I-V) characteristic of the barrier diode shown in FIG. 1A.

FIG. 1C is a graph that illustrates temperature dependent behavior of the barrier diode shown in FIG. 1A.

FIG. 1D is a graph that illustrates another temperature dependent behavior of the barrier diode shown in FIG. 1A.

FIG. 2 is a diagram that illustrates another barrier diode, according to an embodiment.

FIG. 3 is a diagram that illustrates yet another barrier diode, according to an embodiment.

FIG. 4 is a diagram that illustrates yet another barrier diode, according to an embodiment.

FIG. 5A is a graph that illustrates a temperature of a barrier diode.

FIG. 5B is a graph that illustrates a voltage across the barrier diode associated with FIG. 5A.

FIG. 6A is a graph that illustrates a current through a barrier diode that has a heat sink.

FIG. 6B is a graph that illustrates a temperature of the barrier diode associated with FIG. 6A.

FIG. 6C is a graph that illustrates a state of the barrier diode associated with FIGS. 6A and 6B.

FIGS. 7A and 7B illustrate the I-V functionality of a conventional thyristor device in response to a voltage ramp and a current pulse, respectively.

FIGS. 7C and 7D illustrate the I-V functionality of a barrier diode in response to a voltage ramp and a current pulse, respectively.

FIG. 8A is a graph that illustrates an intrinsic temperature of a barrier diode versus impurity concentration of a dopant within a substrate of the barrier diode.

FIG. 8B is a graph that illustrates different secondary breakdown temperatures of different barrier diodes.

FIG. 9 is a schematic of an input power protection device.

FIG. 10A is a block diagram that illustrates a top view of components of an input power protection device.

FIG. 10B is a block diagram that illustrates a side view of the components of the input power protection device shown in FIG. 10A.

FIG. 11A is a schematic of an input power protection device including a polymer positive temperature coefficient (PPTC) device and a barrier diode.

FIG. 11B is a graph that illustrates the behavior of the PPTC device shown in FIG. 11A.

FIGS. 12A and 12B are graphs that illustrate operation of an input power protection device.

FIGS. 13A and 13B are also graphs that illustrate operation of an input power protection device.

FIG. 14A is a side view of an input power protection device, according to an embodiment.

FIG. 14B is a top view of the input power protection device shown in FIG. 14A, according to an embodiment.

### DETAILED DESCRIPTION

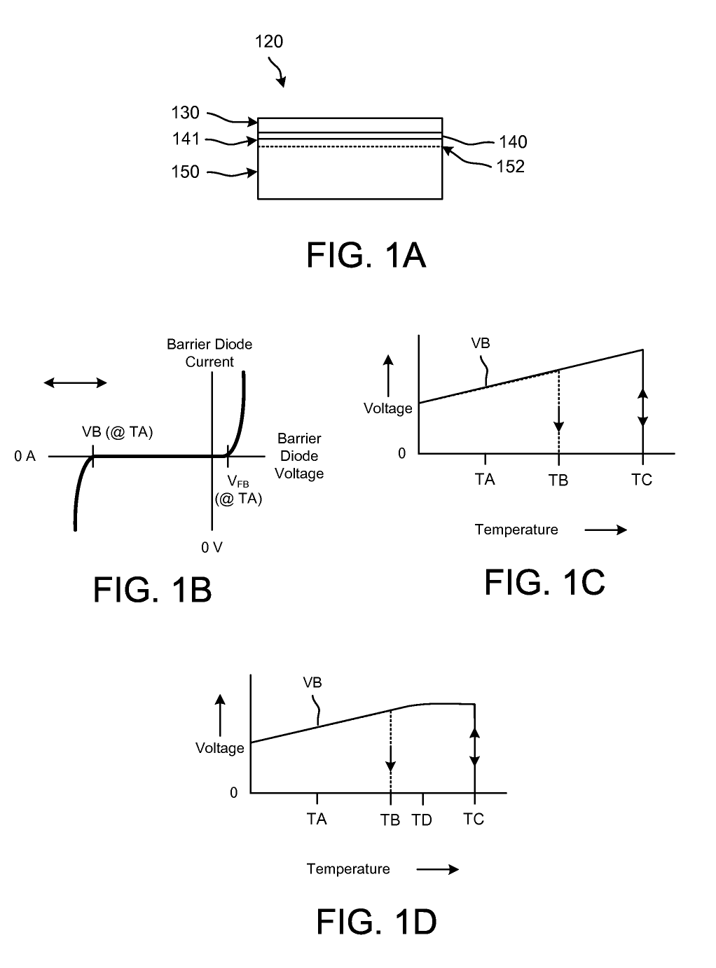

FIG. 1A is a diagram that illustrates a barrier diode 120, according to an embodiment. As shown in FIG. 1A, the barrier diode 120 includes a conductor 130 (also can be referred to as a metal conductor or as a conductor layer), a refractory metal layer 140, and a silicon substrate 150 (also can be referred to as a substrate or die). As shown in FIG. 1A, the refractory metal layer 140 is disposed between the silicon substrate 150 and the metal conductor 130. In some embodiments, the conductor 130, which can serve as a terminal (or ohmic contact) for the barrier diode 120, can include various types of conductive materials such as aluminum (Al), nickel (Ni), copper (Cu), gold (Au), and/or so forth. In some embodiments, the conductor 130 can function as an input terminal of the barrier diode 120. Although not shown in FIG. 1A, the barrier diode 120 can also include an additional conductor (or conductor layer) coupled to a bottom portion of the substrate 150 as a ground terminal, or as an output terminal. In some embodiments, a refractory metal layer can be disposed between the additional conductor and the bottom portion of the substrate 150.

As illustrated by the dashed line, the silicon substrate 150 includes (or is associated with) at least a portion of a PN junction 152 (which is formed with a p-type semiconductor and an n-type semiconductor). In some embodiments, the PN junction 152 can be produced in a single or multiple crystals of semiconductor by doping, for example, using ion implantation, diffusion of dopants, epitaxial growth, and/or so forth. In some embodiments, the barrier diode 120 can be a semiconductor device formed using in any type of semiconductor material such as, for example, silicon (e.g., a doped silicon), gallium arsenide, germanium, silicon carbide, and/or so forth.

FIG. 1B is a graph that illustrates a current versus voltage (I-V) characteristic of the barrier diode 120 shown in FIG. 1A. In FIG. 1B, current through the barrier diode 120 is shown along the y-axis and a voltage across the barrier diode 120 is shown along the x-axis. The current versus voltage characteristic of the barrier diode 120 shown in FIG. 1B is at a temperature TA. As shown in FIG. 1B, the barrier diode 120 has a current versus voltage characteristic that is similar to that of a diode (e.g., typical diode), TVS diode (e.g., a zener diode). The barrier diode 120 operates in a forward-biased mode between 0 volts and a forward bias voltage (V_{FB}), and the barrier diode 120 operates in a reverse-biased mode between 0 volts and a breakdown voltage (VB). If the PN junction 152 of the semiconductor substrate 150 is heavily doped such that the barrier diode 120 functions as a zener diode, the breakdown voltage VB can be referred to as a zener voltage. Although this embodiment, and many of the embodiments described herein, are discussed in the context of a zener diode, any type of overvoltage protection portion may be used with, or instead of, the zener diode. For example, the barrier diode 120 could be any type of TVS device.

In some embodiments, the barrier diode 120 can function in a voltage regulation state (or mode) where the breakdown voltage VB can be used to limit or clamp a voltage from, for example, a power supply (not shown) (e.g., an upstream power supply) and/or can clamp a voltage across a downstream load (not shown). In other words, when in the voltage regulation state, the barrier diode 120 can be configured to limit (e.g., clamp) a voltage across a downstream load at the breakdown voltage VB which can be referred to as a voltage limit or as a clamping voltage. If the barrier diode 120 is, or includes, a zener diode, the zener diode can be configured to limit a voltage across the zener diode at a zener breakdown voltage when in the voltage regulation state.

Referring back to FIG. 1A, the refractory metal layer 140 can include one or more refractory metal elements. The refractory metal elements can include fifth period and sixth period elements from the periodic table of elements such as niobium (Nb), molybdenum (Mo), tantalum (Ta), tungsten (W), and/or rhenium (Re). In some embodiments, the refractory metal elements can include, for example, titanium (Ti), vanadium (V), chromium (Cr), zirconium (Zr), ruthenium (Ru), rhodium (Rh), hafnium (Hf), osmium (Os), and/or iridium (Ir). As a specific example, the refractory metal layer 140 can be, or can include, elemental titanium (Ti), a titanium tungsten (TiW) alloy, a titanium nickel (TiNi) alloy, titanium silver (TiAg) alloy, and/or so forth. In some embodiments, the refractory metal layer 140 can be referred to as a barrier layer, or as a refractory layer. As shown in FIG. 1A, an interface 141 defined by the refractory metal layer 140 and the silicon substrate 150 is parallel to (or approximately parallel to) the PN junction 152. The barrier layer can be formed using any type of metal structure on the silicon substrate 150 that is defined so that metal to PN junction 152 diffusion does not occur (e.g., substantially does not occur, occurs at negligible levels) until temperatures are reached where significant and/or apparent thermal breakdown begins. The thermal breakdown can include thermal leakage roll-over and/or secondary breakdown—both of which are described in more detail below.

The refractory metal layer 140 can be configured to prevent (substantially prevent) diffusion (or migration) of portions (e.g., atoms, ions) of the conductor 130 into the substrate 150 (e.g., into the PN junction 152 of the substrate 150). The diffusion of one or more portions of a conductor into a substrate of a diode (without the refractory metal layer) can be accelerated by a temperature of the diode (or portion thereof) at or exceeding a threshold diffusion temperature (which is a temperature at which diffusion of the conductor into the substrate occurs at a rapid enough rate to generate shorting in response to a fault event). The diffusion of one or more portions (e.g., atoms, molecules) of the conductor into the substrate can cause the diode to change to a shorted state (or mode). The shorted state can be considered a failure mode of the diode where a physical change in the structure (e.g., the semiconductor substrate) of the diode causes the shorting. The shorted state can be an irreversible or permanent (e.g., cannot be recovered) physical change that can cause voltage foldback (i.e. breakdown) of the diode. In some embodiments, the voltage foldback that occurs at temperatures at or exceeding the threshold diffusion temperature can be referred to as diffusion breakdown or as metal diffusion foldback. For example, in a zener diode, diffusion (or migration) of metals of a conductor across the PN junction of the zener diode in response to a temperature above the threshold diffusion temperature of the zener diode can result in an irreversible metal short within the zener diode (e.g., across the PN junction).

Accordingly, the refractory metal layer 140 of the barrier diode 120 can function as a barrier (e.g., a diffusion barrier) that prevents (or substantially prevents) diffusion of portions of the conductor 130 into the substrate 150 at temperatures above the threshold diffusion temperature. Thus, without the refractory metal layer 140, one or more portions of the conductor 130 could migrate into the substrate 150 and could cause the barrier diode 120 to conduct current through the substrate 150 at temperatures above the threshold diffusion temperature.

The presence of the refractory metal layer 140 within the barrier diode 120 can prevent (or substantially prevent) a shorted state of the barrier diode 120 at the threshold diffusion temperature, but the presence of the refractory metal layer 140 between the conductor 130 and the substrate 150 of the barrier diode 120 can allow for a different voltage foldback mechanism (referred to as a secondary foldback) that occurs at secondary breakdown temperature that is higher than (e.g., typically higher than) the threshold diffusion temperature. In some embodiments, this voltage foldback mechanism can be a reversible (e.g., resettable) mechanism that occurs in response to carrier density dependencies. In some embodiments, the barrier diode 120 can be referred to as being in a temperature-induced conduction state (or mode) when carrier density dependencies can cause voltage foldback of the barrier diode 120. In some embodiments, the temperature-induced conduction state can also be referred to as a secondary breakdown state. In some embodiments, the voltage foldback of the barrier diode 120 at the secondary breakdown temperature can be referred to as secondary breakdown of the barrier diode 120. In some embodiments, the secondary breakdown temperature can also be referred to as a threshold carrier temperature.

FIG. 1C is a graph that illustrates temperature dependent behavior of the barrier diode 120 shown in FIG. 1A. Temperature of the barrier diode 120 is increasing to the right along the x-axis and voltage across the barrier diode 120 is increasing vertically along the y-axis. The graph illustrates that the breakdown voltage VB of the barrier diode 120 increases as temperature of the barrier diode 120 increases. Thus, the breakdown voltage VB shown in FIG. 1B can move to the left along the barrier diode voltage axis in response to increasing temperature, and can move to the right along the barrier diode voltage axis in response to decreasing temperature. FIG. 1C illustrates the impact of temperature TA on VB of the I-V curve snapshot shown in FIG. 1B.

The graph in FIG. 1C illustrates voltage foldback (e.g., carrier foldback, secondary breakdown) of the barrier diode 120 at a secondary breakdown temperature TC (or threshold carrier temperature). As represented by the double-sided arrow in FIG. 1C, the voltage foldback (or secondary breakdown) of the barrier diode 120 is reversible (or substantially reversible (given appropriate conditions)). In some embodiments, the voltage foldback of the barrier diode 120 at the secondary breakdown temperature TC can be referred to as secondary breakdown of the barrier diode 120. In some embodiments, the secondary breakdown temperature TC can be between 100° C. and 600° C. In some embodiments, the secondary breakdown temperature TC can be greater than 600° C.

The graph also illustrates the theoretical voltage foldback (e.g., diffusion foldback) at the threshold diffusion temperature TB (as represented by the dashed line) if the barrier diode 120 shown in FIG. 1A did not include the refractory metal layer 140. As represented by the single-sided arrow in FIG. 1C, the carrier foldback (or diffusion breakdown) is irreversible (or substantially irreversible). In some embodiments, the threshold diffusion temperature TB can be between 300° C. and 400° C. In some embodiments, the threshold diffusion temperature TB can be less than 300° C., or can be greater than 400° C. In some embodiments, the voltage foldback (or breakdowns) shown at the threshold diffusion temperature TB and at the secondary breakdown temperature TC can each be referred to as crowbar breakdowns.

The secondary breakdown characteristics of the barrier diode 120 that result from the inclusion of the refractory metal layer 140 between the conductor 130 and the substrate 150 can be used in a variety of applications. For example, the barrier diode 120 can be included in an input/output power protection device that can be used in any type of electronic device related to lighting applications, automobile applications, air-conditioning applications, portable computing device applications, industrial applications, telecom, and/or so forth.

As a specific example, the reversibility of the secondary breakdown can be used (e.g., leveraged) to enhance transient and/or overvoltage energy absorption capabilities of the barrier diode 120 in a variety of applications (e.g., power input/output protection applications). In some embodiments, the secondary breakdown, which occurs at a higher temperature than the threshold diffusion temperature, can be used (e.g., leveraged) instead of being limited by the threshold diffusion temperature to enhance transient and/or overvoltage energy absorption capabilities of the barrier diode 120 in a variety of applications. In some embodiments, the secondary breakdown temperature of the barrier diode 120 can be achieved by heat conducted from one or more portions of the barrier diode 120 and/or one or more devices near and/or coupled to the barrier diode 120 (e.g., coupled to the conductor 130 of the barrier diode 120).

In some embodiments, because the breakdown temperature of secondary breakdown is higher than the diffusion-type breakdown associated with the threshold diffusion temperature, the barrier diode 120 can provide higher energy absorption per unit area in applications than would be possible without the presence of the refractory metal layer 140. In some embodiments, diffusion-based cycling failure modes (e.g., failing short due to metal diffusion) can be avoided (or substantially avoided) by using the barrier diode 120 in some applications (e.g., applications using integrated heating devices (such as a fuse and/or a PTC), application subject to repeated power cycling). In some embodiments, the characteristics of the secondary breakdown, which is a reversible (or substantially reversible mechanism), can be used in some applications that may otherwise be limited by the irreversible diffusion breakdown mechanism. In other words, the barrier diode 120 can be used in place of a typical diode, which is susceptible to diffusion breakdown, in some applications.

In some embodiments, the barrier diode 120 can be configured (e.g., can be defined) using, for example, one or more dopant levels, specified types of refractory metals, and/or so forth, so that the barrier diode 120 achieves secondary breakdown at a specified secondary breakdown temperature (e.g., critical temperature). In some embodiments, the barrier diode 120 can be configured so that the secondary breakdown temperature of the barrier diode 120 is lower than the threshold diffusion temperature of a diode without a refractory metal layer. In some embodiments, the barrier diode 120 can have a secondary breakdown temperature that is configured so that one or more connections (e.g., soldered connections) to the barrier diode 120 may not melt in an undesirable fashion (and result in the barrier diode 120 becoming separated from a board (e.g., a printed circuit board (PCB))). Use of the refractory metal layer 140 within the barrier diode 120 can enable the barrier diode 120 to recoverably operate, after secondary breakdown, longer than would be possible without the refractory metal layer 140 included in the barrier diode 120 (i.e., in a typical diode or zener diode).

As mentioned above, the barrier diode 120 can be used in a variety of devices. For example, the barrier diode 120 can be included in an input power protection device (not shown) configured to provide power protection to a load (not shown) from one or more undesirable power conditions. In some embodiments, the undesirable power conditions (which can include an overvoltage condition and/or an overcurrent condition) such as a voltage spike (related to power supply noise) and/or a current spike (caused by a downstream overcurrent event such as a short) may be produced by a power supply (not shown). For example, the load may include electronic components (e.g., sensors, transistors, microprocessors, application-specific integrated circuits (ASICs), discrete components, circuit board) that could be damaged in an undesirable fashion by relatively fast increases in current and/or voltage produced by the power supply. Accordingly, the input power protection device can be configured to detect and prevent these relatively fast increases in current and/or voltage from damaging the load and/or other components associated with the load (such as a circuit board). In some embodiments, the input power protection device can include an integrated overcurrent protection device (e.g., a polymer positive temperature coefficient (PPTC) device (or PTC device), a fuse, a silicon current limit switch, a polysilicon-based fuse, an electronic fuse (e-fuse), a ceramic positive temperature coefficient (CPTC) device) and the barrier diode 120 such that the input power protection device can have a longer cycle life, lower cost/performance characteristics, and/or handle higher power than would be possible using, for example, a typical zener diode integrated with the overcurrent protection device in the input power protection device. In some embodiments, heat can be transferred between components of the input power protection device such as heat transferred from a barrier diode to a PPTC, and vice versa, for various functional purposes.

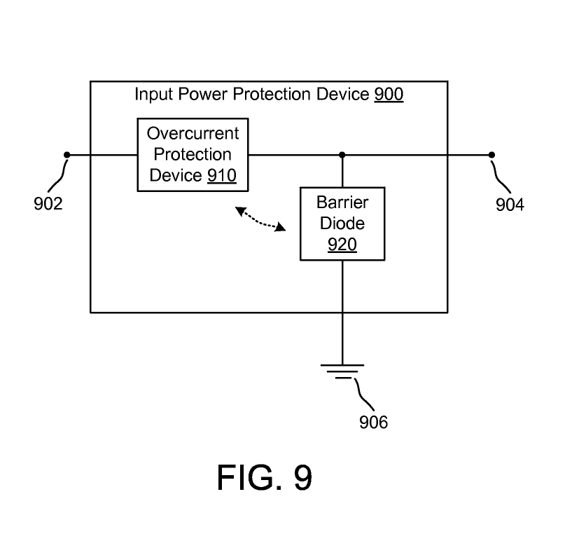

As another example, the barrier diode 120 can be used as a two terminal (e.g., two pin) device that emulates the functionality of a zener diode in combination with a silicon-controlled rectifier (SCR) and a timing circuit device (e.g., a delay circuit device). In some embodiments, the combination of the zener diode, silicon-controlled rectifier (SCR), and timing circuit device can collectively be referred to as a SCR circuit. At least some of the applications of the barrier diode 120 mentioned above are described in more detail below in connection with the figures. For example, more details related to a barrier diode being used to perform SCR functionality are described in connection with, for example, FIGS. 4 through 7D, and implementations of an input power protection device including a barrier diode are described in connection with, for example, FIG. 9.

FIG. 1D is a diagram that illustrates another temperature dependent behavior of the barrier diode 120 shown in FIG. 1A. The temperature of the barrier diode 120 is increasing to the right along the x-axis and voltage across the barrier diode 120 is increasing vertically along the y-axis. The graph illustrates that the breakdown voltage VB of the barrier diode 120 increases as temperature of the barrier diode 120 increases.

As shown in FIG. 1D, the breakdown voltage VB is non-linear with respect to temperature. The breakdown voltage VB increases linearly (e.g., approximately linearly) with temperature until approximately temperature TD, which in this example, is between the threshold diffusion temperature TB and the secondary breakdown temperature TC. As shown in FIG. 1D, the increase in the breakdown voltage VB with respect to temperature after temperature TD tapers (e.g., levels off, reaches a voltage limit, or in some cases begins to decline in a relatively smooth manner).

Accordingly, the breakdown voltage VB can behave (e.g., increase) with respect to temperature based on a first relationship (e.g., a linear relationship) before temperature TD and can behave (e.g., increase, taper, decrease) based on a second relationship (e.g., a non-linear relationship, a linear relationship with a different slope) with respect to temperature after temperature TD. In some embodiments, the breakdown voltage VB can decrease with respect to the temperature after temperature TD.

In some embodiments, the temperature at which the behavior of the barrier diode 120 changes can vary. For example, a barrier diode can be configured (e.g., configured with a barrier layer) so that the change in breakdown voltage VB versus temperature occurs a temperature that is closer to the threshold diffusion temperature than the secondary breakdown temperature, or vice versa. In some embodiments, the behavior of the barrier diode 120 can change multiple times at multiple different temperatures between temperature TB and temperature TC.

In some embodiments, the temperature TD can be a temperature at which thermal leakage roll-over occurs. Accordingly, the temperature TD can be referred to as a thermal leakage roll-over temperature or a taper temperature. In some embodiments, the behavior of the barrier diode 120 shown in FIG. 1D can be advantageous in some input power protection designs. As the temperature of the barrier diode 120 increases beyond temperature TD, the breakdown voltage VB can taper so that the voltage across downstream devices (which are electrically coupled to the barrier diode 120 and can have voltages that change as the breakdown voltage VB changes) may also taper.

In some embodiments, the behavior of the barrier diode 120 after approximately temperature TD can vary based on a voltage rating of the barrier diode 120. Specifically, tapering of breakdown voltage VB with respect to temperature can increase with increased voltage rating of a barrier diode. For example, a 4 V barrier diode can taper with respect to temperature to a lesser extent than a 16 V barrier diode.

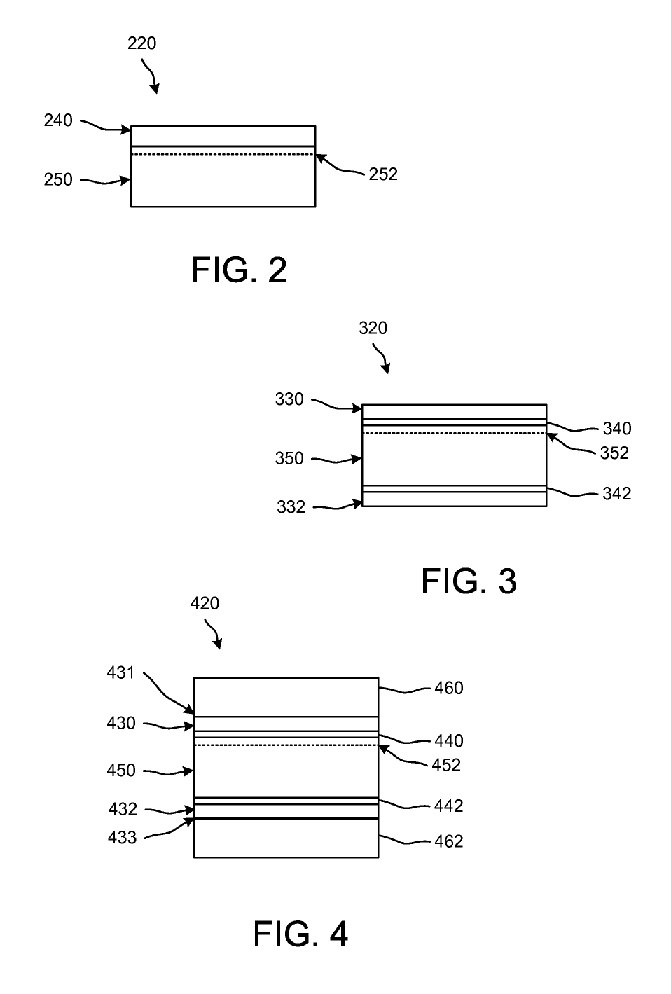

FIG. 2 is a diagram that illustrates another barrier diode 220, according to an embodiment. As shown in FIG. 2, the barrier diode 220 includes a refractory metal layer 240 and a substrate 250. In this embodiment, the barrier diode 220 does not include a conductor coupled to the refractory metal layer 240. Instead, the refractory metal layer 240 functions as a terminal (e.g., an input terminal) or as a contact of the barrier diode 220.

FIG. 3 is a diagram that illustrates yet another barrier diode 320, according to an embodiment. As shown in FIG. 3, the barrier diode 320 includes a substrate 350 coupled to a refractory metal layer 340 and a refractory metal layer 342. The refractory metal layer 340 functions as a diffusion barrier between a metal conductor 330 and the substrate 350, and the refractory metal layer 342 function as a diffusion barrier between a metal conductor 332 and the substrate 350. The metal conductor 330 can function as an input terminal of the barrier diode 320, and the metal conductor 332 can function as an output terminal (or as a ground terminal) of the barrier diode 320.

In some embodiments, the metal conductor 330 can be the same type of metal as the metal conductor 332. For example, the metal conductor 330 and the metal conductor 332 can both be made of aluminum. In some embodiments, the metal conductor 330 can be a different type of metal than the metal conductor 332. For example, the metal conductor 330 can be made of aluminum and the metal conductor 332 can be made of nickel.

In some embodiments, the refractory metal layer 340 can be made of the same type of material as the refractory metal layer 342. For example, both the refractory metal layer 340 and the refractory metal layer 342 can be made of a titanium tungsten alloy. In some embodiments, the refractory metal layer 340 and the refractory metal layer 342 can be made of different materials. For example, the refractory metal layer 340 can be made of elemental titanium, and the refractory metal layer 342 can be made of a titanium tungsten alloy.

FIG. 4 is a diagram that illustrates yet another barrier diode 420, according to an embodiment. As shown in FIG. 4, the barrier diode 420 includes a substrate 450 coupled to a refractory metal layer 440 and a refractory metal layer 442. The refractory metal layer 440 functions as a diffusion barrier between a metal conductor 430 and the substrate 450, and the refractory metal layer 442 function as a diffusion barrier between a metal conductor 432 and the substrate 450. The metal conductor 430 can function as an input terminal of the barrier diode 420, and the metal conductor 432 can function as an output terminal (or as a ground terminal) of the barrier diode 420.

As shown in FIG. 4, a heat sink 460 is coupled to the metal conductor 430 and a heat sink 462 is coupled to the metal conductor 432. The heat sinks 460, 462 are configured to conduct heat away from the conductors 430, 432, the refractory metal layers 440, 442, the substrate 450, and/or the PN junction 452. In some embodiments, the heat sinks 460, 462 can be configured to draw heat away so that a change of the barrier diode 420 from a voltage regulation state to a temperature-induced conduction state can be delayed. In other words, the amount of heat required to change the barrier diode 420 from the voltage regulation state to the temperature-induced conduction state can be greater than would otherwise be required without the heat sinks 460, 462.

In some embodiments, the heat sinks 460, 462 can include various types of conductive materials such as aluminum (Al), nickel (Ni), copper (Cu), gold (Au), and/or so forth. In some embodiments, one or more of the heat sinks 460, 462 can be made of an electrically insulating material such as a high-temperature polymer-based material. In some embodiments, the heat sink 460 can be made of the same type of material as the heat sink 462. For example the heat sink 460 and the heat sink 462 can both be made of copper. In some embodiments, the heat sink 460 can be made of a different material than the heat sink 462.

In some embodiments, one or more of the heat sinks 460, 462 can have a different structure than that shown in FIG. 4. For example, one or more of the heat sinks 460, 462 can have a fin-type structure. In some embodiments, one or more the heat sinks 460, 462 can be removably coupled to the barrier diode 420. In such embodiments, one or more of the heat sinks 460, 462 can be configured to interface with one or more of the metal conductors 430, 432, and can be configured to be coupled to one or more of the metal conductors 430, 432 using, for example, a mechanical mechanism such as solder, a glue (e.g., an epoxy), a press fit, and/or so forth.

In this embodiment, the heat sinks 460, 462 are made of a different material than the metal conductors 430, 432. In some embodiments, the metal conductors 430, 432 can be configured so that they function as one or more heat sinks for the barrier diode 420.

Although not shown in FIG. 4, in some embodiments, the barrier diode 420 can include a single heat sink rather than two heat sinks 460, 462. For example, the barrier diode 420 can include only heat sink 460 or only heat sink 462.

Also as shown in FIG. 4, each of the heat sinks 460, 462 have a thickness that is greater than the thickness of each of the metal conductors 430, 432. In some embodiments, each of the heat sinks 460, 462 can have a thickness that is less than or equal to the thickness of each of the metal conductors 430, 432. In some embodiments, one or more of the heat sinks 460, 462 can have a volume that is smaller than a volume of one or more of the metal conductors 430, 432.

In some embodiments, one or more of the heat sinks 460, 462 can be configured so that a cross-sectional area of the one or more heat sinks 460, 462 is smaller than a cross-sectional area of one or more of the metal conductors 430, 432. For example, the heat sink 460 can be configured so that a surface 431 of the metal conductor 430 is not entirely covered by the heat sink 460.

In some embodiments, one or more characteristics of the conductors 430, 432, the heat sinks 460, 462, and/or the refractory metal layers 440, 442 (or of any of the conductors, the heat sinks, and/or the refractory metal layers described herein) can vary. For example, a thermal conductivity of the heat sink 460 can vary vertically (between top and bottom) and/or can vary horizontally (between the left and right or between the front and back). As a specific example, a thermal conductivity of the heat sink 460 can be higher towards the edges of the heat sink 460 than a center portion of the heat sink 460. In such embodiments, heat can be conducted by the heat sink 460 from the remaining portions of the barrier diode 460 more rapidly at the edges of the heat sink 460 than by the center portion of the heat sink 460.

Although not shown in FIG. 4, in some embodiments, a thickness of one or more of the conductors 430, 432, the heat sinks 460, 462, and/or the refractory metal layers 440, 442 can vary, for example, horizontally. As a specific example, the thickness of the heat sink 460 can taper from the left to the right. Similarly, in some embodiments, a width/length of the heat sink 460 can vary.

In some embodiments, the size (or mass) of the heat sinks 460, 462 can be configured to modify a time during which heat applied to the barrier diode 420 will trigger the barrier diode 420 to change from a voltage regulation state to a temperature-induced conduction state. For example, the heat sink 460 can be sized so that the barrier diode 420 will change from a voltage regulation state to a temperature-induced conduction state in response to a specified current flowing through the barrier diode 420 (which can cause Joule heating or IV heating) for a specified period of time. As another example, the heat sink 460 can be sized such that the barrier diode 420 will change from a voltage regulation state to a temperature-induced conduction state in response to a specified amount (e.g., level) of heat transferred from a component (e.g., a component such as a resistor functioning as a heating element) near the barrier diode 420 during a specified period of time.

In some embodiments, a size (e.g., a thickness, a height, a width, a mass) of the substrate 450 can be modified so that the temperature-induced conduction state may be changed. For example, a thickness of the substrate 450 can be defined (e.g., decreased, thinned) so that the temperature-induced conduction state may occur more quickly in response to a specified quantity of heat than would otherwise occur if the thickness of the substrate 450 were greater. In some embodiments, the elements illustrated in FIGS. 1A through 4 (e.g., heat sinks, conductors, substrates) can be included in a barrier diode in any combination.

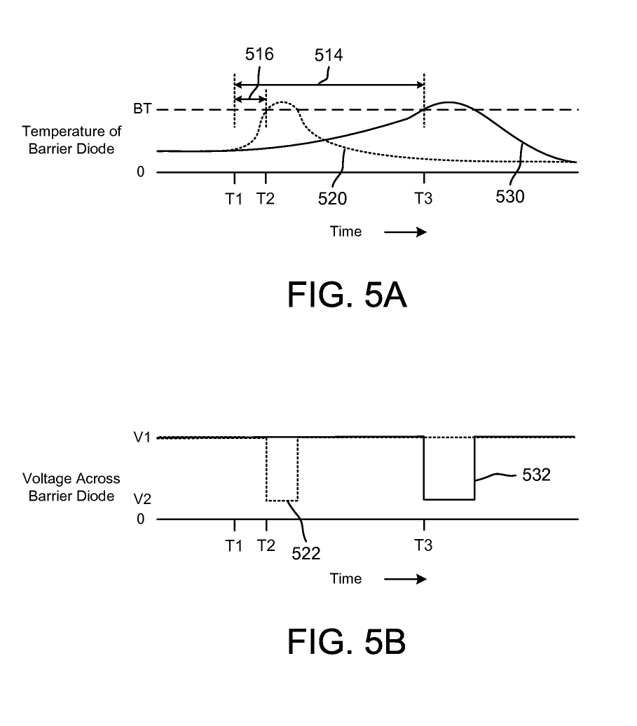

FIGS. 5A and 5B collectively illustrate the effect of a heat sink coupled to a barrier diode, according to an embodiment. FIG. 5A is a graph that illustrates a temperature of a barrier diode, and FIG. 5B is a graph that illustrates a voltage across the barrier diode associated with FIG. 5A. In FIGS. 5A and 5B, time is increasing to the right. The dashed lines (520, 522) are related to a barrier diode without a heat sink (such as barrier diode 320 shown in FIG. 3) and the solid lines (530, 532) are related to a barrier diode with a heat sink (such as barrier diode 420 shown in FIG. 4).

In FIG. 5A, approximately the same level (e.g., quantity and rate) of heat (or power) is applied to the barrier diode without the heat sink (represented by dashed line 520) and applied to the barrier diode with the heat sink (represented by solid line 530) starting at time T1 until the secondary breakdown temperature BT is reached. As shown in FIG. 5A, the barrier diode without the heat sink (represented by dashed line 520) is heated to the secondary breakdown temperature BT faster than the barrier diode with the heat sink (represented by solid line 530) is heated to the secondary breakdown temperature BT. Specifically, the barrier diode without the heat sink is heated to the secondary breakdown temperature BT during time period 516 between times T1 and T2, and the barrier diode with the heat sink is heated to the secondary breakdown temperature BT during time period 514 between times T1 and T3. The heating of the barrier diode with the heat sink is delayed because the heat sink (e.g., the mass of the heat sink) conducts heat away from a semiconductor of (e.g., the PN junction of) the barrier diode.

FIG. 5B illustrates that the secondary breakdown, or secondary voltage foldback, of the barrier diode without the heat sink (represented by dashed line 522) occurs at time T2, which corresponds with the time at which the barrier diode is heated to the secondary breakdown temperature BT. In this embodiment, the voltage across the barrier diode without the heat sink changes from a voltage V1 to a relatively low voltage V2 at time T2. The secondary breakdown, or voltage foldback, of the barrier diode with the heat sink (represented by solid line 532) occurs at time T3, which corresponds with the time at which the barrier diode is heated to the secondary breakdown temperature BT. In this embodiment, the voltage across the barrier diode with the heat sink changes from a voltage V1 to a relatively low voltage V2 at time T3.

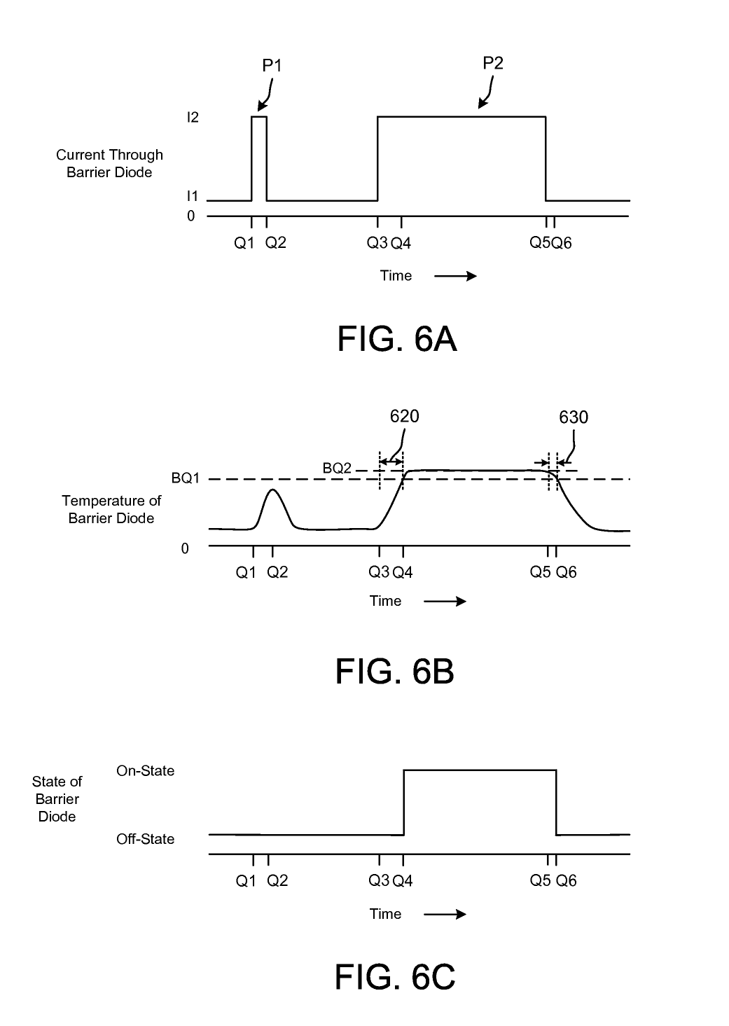

As mentioned previously, the characteristics of a barrier diode with a heat sink can be used as a two terminal (e.g., two pin) device that emulates the functionality of a zener diode in combination with a SCR and a timing circuit device (e.g., a delay circuit device). The functionality of such a device is described in connection with FIGS. 6A through 6C.

FIGS. 6A through 6C collectively graphically illustrate functionality of a barrier diode with a heat sink that is a two terminal (e.g., two pin) device configured to emulate the functionality of a zener diode in combination with a SCR and a timing circuit device. The barrier diode, rather than being voltage (or gate) triggered is temperature triggered. In FIGS. 6A through 6C, time is increasing to the right. In some embodiments, the barrier diode discussed in connection with FIGS. 6A through 6C can be similar to the barrier diode 420 shown in FIG. 4, which is a barrier diode that has at least one heat sink.

FIG. 6A is a graph that illustrates a current through a barrier diode that has a heat sink. As shown in FIG. 6A, a current pulse is applied to the barrier diode between times Q1 and Q2 (which can be referred to as current pulse P1) and between times Q3 and Q5 (which can be referred to as current pulse P2). The current pulse P1 has a duration that is shorter than a duration of current pulse P2. The current pulse P1 and the current pulse P2 have the same amplitude that changes from current I1 to current I2.

FIG. 6B is a graph that illustrates a temperature of the barrier diode associated with FIG. 6A. As shown in FIG. 6B, the temperature of the barrier diode increases starting at approximately time Q1 in response to the current pulse P1. The temperature of the barrier diode, however, is below the secondary breakdown temperature BQ1, and starts decreasing (e.g., through a conduction or convection mechanism) at approximately the end of the current pulse P1 starting at time Q2.

As shown in FIG. 6B, the temperature of the barrier diode starts increasing approximately time Q3 in response to the current pulse P2. The temperature of the barrier diode, in this case, increases beyond the secondary breakdown temperature BQ1 at approximately time Q4. The temperature of the barrier diode starts decreasing approximately time Q5, which corresponds with the end time of the current pulse P2, until the temperature of the barrier diode falls below the secondary breakdown temperature BQ1 at approximately time Q6.

As shown in FIG. 6B, the temperature of the barrier diode remains above the secondary breakdown temperature BQ1 between times Q4 and Q6, and is at a steady-state temperature BQ2 shortly after time Q4 and until approximately time Q5. The temperature of the barrier diode remains above the secondary breakdown temperature BQ1 (at the steady state temperature BQ2) in response to heating (e.g., IV heating, Joule heating) caused by the current of the pulse P2 remaining at current I2. Accordingly, the temperature of the barrier diode falls (e.g., through a conduction or convection mechanism) below the secondary breakdown temperature BQ1 in response to the current of the pulse P2 decreasing. Although not shown in FIG. 6A through 6C, in some embodiments, the temperature of the barrier diode can be decreased using a device separate from the barrier diode such as a cooling element.

FIG. 6C is a graph that illustrates a state of the barrier diode associated with FIGS. 6A and 6B. As shown in FIG. 6C, the barrier diode is in an off-state (e.g., a voltage regulation state), and at approximate time Q4 the barrier diode changes to an on-state (e.g., a temperature-induced conduction state) in response to the temperature of the barrier diode exceeding the secondary breakdown temperature BQ1 (shown in FIG. 6B). The barrier diode remains latched in the on-state until the temperature the barrier diode falls below the secondary breakdown temperature BQ1 approximately time Q6 (shown in FIG. 6B). The barrier diode remains latched in the on-state in response to the current of the pulse P2 causing the temperature of the barrier diode to remain above the secondary breakdown temperature BQ1 as shown in FIG. 6B. Also, as shown in FIG. 6C, the barrier diode remains in the off-state between times Q1 and Q4 despite the current pulse P1 because the temperature the barrier diode does not increase beyond the secondary breakdown temperature BQ1 in response to the current pulse P1. Thus, the changing of the barrier diode between the off-state and the on-state is triggered by the temperature of the barrier diode, and the barrier diode can remain latched in the on-state in response to current I2 through the barrier diode.

In some embodiments, the current to maintain the barrier diode latched in the on-state can be referred to as a hold current. In some embodiments, the minimum current to maintain the barrier diode latched in the on-state can be referred to as a hold current. In some embodiments, the current to maintain the barrier diode latched in the on-state can be less than the current I2 through the barrier diode.

The barrier diode (which includes a refractory metal diffusion barrier with a thermal mass (i.e., heat sink) and has the functionality illustrated in FIG. 6A through 6C) can be used to create a simple, single two-pin device (with a single PN junction) that is functionally equivalent to, or approximately functionally equivalent to, an integrated clamping device and time-delayed SCR device (or thyristor device) with a timing circuit. These SCR devices would typically have at least three pins, where one of the pins is a voltage controlled gate. Also, the SCR devices typically have multiple PN junctions that are serially coupled. In this embodiment, the secondary voltage foldback of the barrier diode is temperature driven, which is contrasted with a voltage driven SCR-based device. Also, latching in the on-state shown in FIGS. 6A through 6C is thermally induced using an IV mechanism from the current I2 of the pulse P2. Latching within an SCR-based device is maintained through current injection. In some embodiments, when the barrier diode is in the off-state the current through the barrier diode can be approximately a leakage current through the barrier diode.

In some embodiments, the thermal characteristics (e.g., properties) of the barrier diode such as the mass of the heat sink coupled to the barrier diode, thickness of the substrate of the barrier diode, and/or so forth can be used to control the foldback timing of the barrier diode. In other words, the pulse characteristics (e.g., duration, amplitude) required to cause the temperature of the barrier diode to increase beyond the secondary breakdown temperature BQ1 can be defined using the characteristics of the barrier diode such as the mass of the heat sink, substrate thickness, and/or so forth (and as described in connection with, for example, FIG. 4).

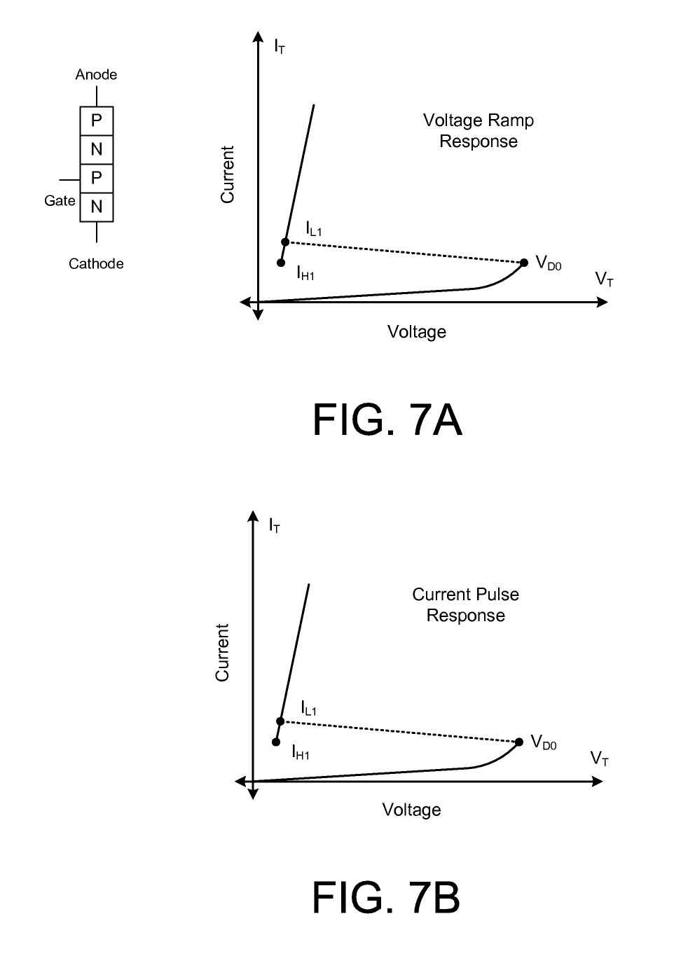

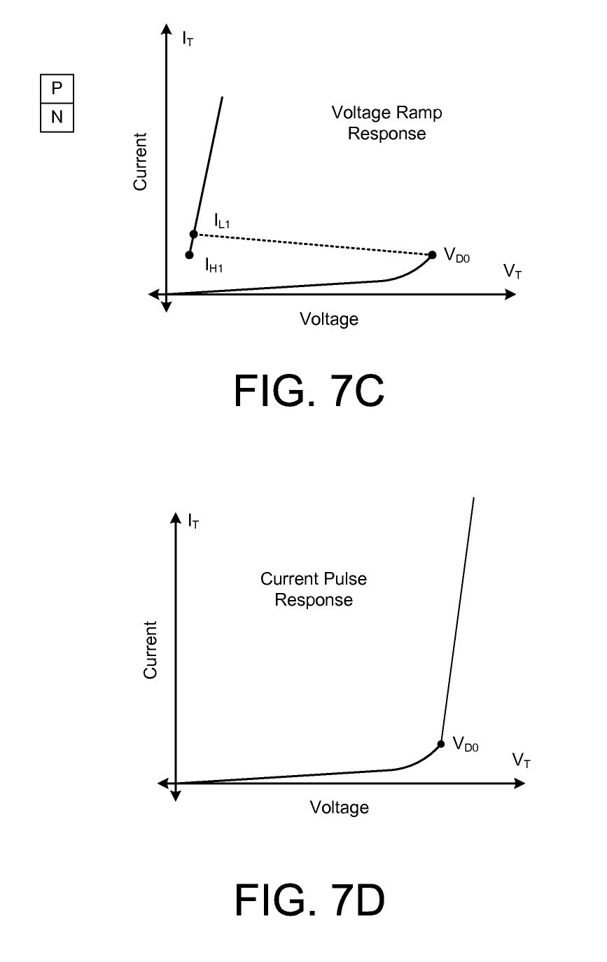

FIGS. 7A and 7B illustrate the I-V functionality of a conventional thyristor device in response to a voltage ramp (e.g., a slow voltage ramp) and a current pulse (e.g., a short current pulse), respectively. As shown in FIGS. 7A and 7B, current through the thyristor (I_{T}) is shown along the y-axis and voltage across the thyristor is shown on the x-axis (V_{T}). As shown in FIGS. 7A and 7B, once the conventional thyristor device has been switched on via a gate terminal, the device remains latched in the on-state (i.e. does not need a continuous supply of gate current to conduct), provided that the anode current has exceeded the latching current (I_{L1}). As long as the anode remains positively biased, the device is not switched off until the anode current falls below the holding current (I_{H1}). In some embodiments, the conventional thyristor device can have multiple PN junctions that are serially coupled.

In the conventional thyristor device, triggering of the conventional thyristor device, using a voltage ramp (as shown in FIG. 7A) or in response to a current pulse (as shown in FIG. 7B), can result in a relatively low voltage condition and can require an upstream power switch event to bring the conventional thyristor device back to a high resistance state. This switching activity can require a power down of the protected system (e.g., a power source) associated with the thyristor device. Although not a desirable solution in many applications, this shortcoming may be rectified by adding a time delay to the thyristor device, or using a parallel zener diode to clamp short transients (such as current pulse) and using the thermal and current-based breakdown voltage drift of the parallel Zener diode to activate the thyristor device in the event of a high power transient.

FIGS. 7C and 7D illustrate the I-V functionality of a barrier diode in response to a voltage ramp (e.g., a slow voltage ramp) and a current pulse (e.g., a short current pulse), respectively. The voltage ramp in the current pulse associated with FIGS. 7C and 7D is the same as (or substantially the same as) the voltage ramp and the current pulse associated with FIGS. 7A and 7B. As shown in FIGS. 7C and 7D, current through the barrier diode (I_{T}) is shown along the y-axis and voltage across the thyristor shown on the x-axis (V_{T}).

As shown in FIG. 7C, once the barrier diode has been switched on in response to a temperature increase, the barrier diode remains latched in the on-state provided that the temperature of the barrier diode remains above the secondary breakdown temperature the barrier diode. In some embodiments, the temperature barrier diode can remain above the secondary breakdown temperature in response to a current through the barrier diode exceeding the latching current (I_{L2}) of the barrier diode. As long as the temperature of the barrier diode is above the secondary breakdown temperature, the barrier diode is not switched off until the latching current (I_{L2}) falls below the holding current (I_{H2}) of the barrier diode. Resetting of the barrier diode can be achieved by cooling the barrier diode to a temperature below the secondary breakdown temperature (e.g., by cutting off a current through the barrier diode).

As shown in FIG. 7D, the voltage across the barrier diode does not foldback in response to the current pulse (in contrast to the response shown in FIG. 7B). Instead, the barrier diode remains in an off-state, or in a voltage regulation state, and the behavior the barrier diode follows the I-V behavior of, for example, a zener diode. In other words, the barrier diode does not conduct current at a folded back voltage as the barrier diode does in an on-state as shown in FIG. 7C. In the embodiment shown in FIG. 7D, because the voltage across the barrier diode does not foldback in response to the current pulse, resetting of the barrier diode is not required and/or a bus operatively coupled to the barrier diode will not droop in response to short transients such as the current pulse.

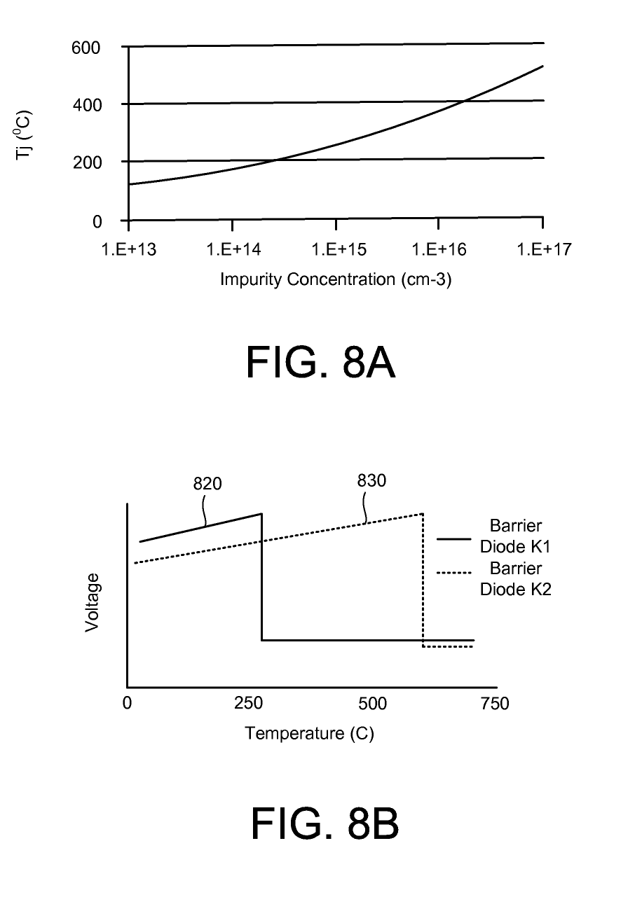

FIG. 8A is a graph that illustrates an intrinsic temperature (Tⱼ) of a barrier diode versus impurity concentration of a dopant within a substrate of the barrier diode. Specifically, the impurity concentration of the doping can be within a PN junction of the substrate of the barrier diode. As shown in FIG. 8A, the intrinsic temperature Tⱼ, which is the temperature at which secondary breakdown within the barrier diode occurs, increases as the impurity concentration within the barrier diode increases and decreases as the impurity concentration within the barrier diode decreases. Accordingly, a barrier diode can be configured, using impurity concentration, to achieve secondary breakdown at a specified temperature. In other words, a secondary breakdown temperature of a barrier diode can be defined using impurity concentration(s) within barrier diode for a particular application and/or component integration scheme.

FIG. 8B is a graph that illustrates different secondary breakdown temperatures of different barrier diodes. Voltage across the barrier diodes is shown on the y-axis, and temperature (e.g., temperature of a PN junction) of the barrier diodes is shown on the x-axis. Specifically, the graph illustrates a breakdown curve 820 of the barrier diode K1 and a breakdown curve 830 the barrier diode K2. As shown in FIG. 8B, the barrier diode K1 has a secondary breakdown temperature at approximately 250° C., and the barrier diode K2 has a secondary breakdown temperature of approximately 600° C. The respective secondary breakdown temperatures of the barrier diodes K1 and K2 can be defined (e.g., set) using specified dopant levels. In this embodiment, the barrier diode K1 has a lower secondary breakdown temperature than the barrier diode K2, because the barrier diode K1 has a lower dopant level than the dopant level of the barrier diode K2.

In some embodiments, the secondary breakdown temperature of the barrier diode can be defined to prevent barrier diode desoldering (e.g., melting of a solder used to couple the barrier diode to a PCB) and/or PCB overheating. Specifically, the secondary breakdown temperature of the barrier diode can be defined so that the barrier diode achieves secondary breakdown before diode desoldering and/or PCB overheating occurs. In some embodiments, the secondary breakdown temperature of the barrier diode can be defined so that the barrier diode achieves secondary breakdown before desoldering and/or PCB overheating occurs during an overvoltage event. For example, if barrier diode desoldering could occur in a particular application at a junction temperature of 550° C., a barrier diode can be configured (using dopant levels) so that the barrier diode has a secondary breakdown temperature below 550° C.

In some embodiments, the secondary breakdown temperature of a barrier diode can be decreased, using lower concentration levels of one or more dopants included in a substrate of the barrier diode, below a diffusion temperature of the barrier diode. In such embodiments, at the relatively low secondary breakdown temperature, the barrier diode will achieve secondary breakdown at a lower steady-state temperature than would otherwise be possible if the barrier diode were configured to breakdown at relatively high secondary breakdown temperature. In some embodiments, this relatively low secondary breakdown temperature can be defined for a barrier diode to enhance protection capabilities of the barrier diode in some applications and to increase survivability of the barrier diode when in secondary breakdown.

In some embodiments, the secondary breakdown temperature of the barrier diode can be defined so that the power capacity of the barrier diode, when in the temperature-induced conduction state (or secondary breakdown state), can be specified (e.g., increased, decreased). For example, the secondary breakdown temperature of the barrier diode can be defined so that the power capacity of the barrier diode, when in the temperature-induced conduction state (or secondary breakdown state), can be higher than would be possible if the secondary breakdown temperature of the barrier diode were higher. For example, a barrier diode can have a particular power rating that represents the maximum power that the barrier diode can handle in a particular application. The secondary breakdown temperature of the barrier diode can be defined so that secondary breakdown occurs at a relatively low temperature. Because the secondary breakdown of the barrier diode occurs at a relatively low temperature, the barrier diode, while in the temperature-induced conduction state, can source a relatively high level of current without the overall power through the barrier diode exceeding the power rating of the barrier diode. The refractory metal layer (e.g., diffusion barrier) of the barrier diode in combination with the dopant levels in the semiconductor of the barrier diode enables defining of the barrier diode secondary breakdown temperature so that the energy capacity (i.e., power handling) of the barrier diode can be relatively high (as described above) after secondary breakdown is achieved.

In some embodiments, the durability of a barrier diode can depend on a secondary breakdown temperature of the barrier diode. In some embodiments, a hotspot within a portion (e.g., within a portion of a substrate/die) of the barrier diode where secondary breakdown is initiated can have a relatively high current concentration (e.g., a relatively high current density). The current concentration at the hotspot, if high enough and/or long enough, can cause damage (e.g., permanent damage) to the barrier diode. In some embodiments, the damage can be caused when a critical failure temperature (which can be referred to as a permanent failure temperature) at the hotspot is exceeded. If the barrier diode has a relatively low secondary breakdown temperature, heat that is produced during secondary breakdown can be transferred (e.g., transferred via conduction) to other portions of the barrier diode before damage occurs at the hotspot and/or so that secondary breakdown of the barrier diode can become more widespread within the barrier diode rather than being localized at the hotspot. In some embodiments, the barrier diode can have a secondary breakdown temperature that is defined so that damage to the barrier diode at one or more hotspots can be minimized and/or reduced. Thus, the durability of the barrier diode can be determined and the barrier diode can be configured with a specified survivability level when in secondary breakdown at a specified secondary breakdown temperature.

In some embodiments, the secondary breakdown temperature of the barrier diode can be defined so that the power capacity (i.e., power handling) of the barrier diode, before the temperature of the barrier diode reaches the secondary breakdown temperature of the barrier diode, can be specified (e.g., increased, decreased). For example, the secondary breakdown temperature of the barrier diode can be defined so that the power capacity of the barrier diode, before the temperature of the barrier diode reaches the secondary breakdown temperature of the barrier diode, can be higher than would be possible if the barrier diode had a lower secondary breakdown temperature. As another example, the secondary breakdown temperature of the barrier diode can be defined so that secondary breakdown occurs at a relatively high temperature. Because the secondary breakdown of the barrier diode occurs at a relatively high temperature, the barrier diode can source a relatively high level of power before reaching the secondary breakdown temperature (and changing from a voltage regulation state to a temperature-induced conduction state). In such embodiments, the refractory metal layer (e.g., diffusion barrier) of the barrier diode enables defining of the barrier diode secondary breakdown temperature so that the energy capacity of the barrier diode can be relatively high before secondary breakdown is achieved.

Although not shown in FIG. 8B, the barrier diode K1 (associated with breakdown curve 820) and the barrier diode K2 (associated with breakdown curve 830) can experience thermal leakage roll-over before their respective secondary breakdown temperature, or even diffusion breakdown temperature. For example, the breakdown voltage of the barrier diode K1 can behave differently with respect to temperature before and after a temperature (e.g., thermal leakage roll-over temperature) between a diffusion breakdown temperature and the secondary breakdown temperature. In some embodiments, the breakdown voltage of the barrier diode can start to taper versus voltage after a specified temperature, which is lower than the secondary breakdown temperature.

FIG. 9 is a schematic of an input power protection device 900. As shown in FIG. 9, the input power protection device 900 includes an overcurrent protection portion 910 (which can be, for example, a fuse device, an e-fuse device, a PPTC (or PTC device), and/or so forth), which functions as an overcurrent protection portion of the input power protection device 900. In some embodiments, the overcurrent protection portion 910 can be formed of any type of material such as, for example, aluminum, tin, copper, lead, conductive polymers, brass, bronze, nichrome, and/or so forth. The input power protection device 900 also includes a barrier diode 920, which functions as an overvoltage protection portion (and can be referred to as an overvoltage protection portion) of the input power protection device 900. In some embodiments, the barrier diode can be the same as, or similar to, any of the barrier diodes described herein.

As shown in FIG. 9, the overcurrent protection portion 910 and the barrier diode 920 are integrated into the input power protection device 900 so that the input power protection device 900 functions as a single, integrated component. In other words, the overcurrent protection portion 910 and the barrier diode 920 can be packaged into the input power protection device 900 so that the input power protection device 900 functions as a standalone discrete component. In some embodiments, the components of the input power protection device 900 may not be integrated into a single component.

The input power protection device 900 is configured to provide power protection to a load (not shown) from one or more undesirable power conditions. In some embodiments, the load may be coupled to an output terminal 904 of the input power protection device 900. In some embodiments, the undesirable power conditions (which can include an overvoltage condition and/or an overcurrent condition) such as a voltage spike (related to power supply noise) and/or a current spike (caused by a downstream overcurrent event such as a short) may be produced by a power supply (not shown). In some embodiments, the power supply can be coupled to an input terminal 902 of the input power protection device 900. For example, the load may include electronic components (e.g., sensors, transistors, microprocessors, application-specific integrated circuits (ASICs), discrete components, circuit board) that could be damaged by relatively fast increases in current and/or voltage produced by the power supply. Accordingly, the input power protection device 900 can be configured to detect and prevent these relatively fast increases in current and/or voltage from damaging the load and/or other components associated with the load (such as a circuit board).

In some embodiments, the overcurrent protection portion 910 and the barrier diode 920 can be included in the input power protection device 900 so that the overcurrent protection portion 910 provides series overcurrent protection and the barrier diode 920 provides shunt to ground overvoltage protection. The series overcurrent protection provided by the overcurrent protection portion 910 and the shunt to ground overvoltage protection provided by the barrier diode 920 can be integrated into a single package of the input power protection device 900 so that the input power protection device 900 is a standalone, discrete component.

The barrier diode 920 of the input power protection device 900 can be configured to protect a load from, for example, sudden or sustained increases in voltage produced by a power supply. In other words, the barrier diode 920 of the input power protection device 900 can be configured to provide voltage protection to the load in response to, for example, an overvoltage event. In some embodiments, the barrier diode 920 of the input power protection device 900 can be configured to protect the load from voltage produced by the power supply based on one or more voltage conditions (e.g., a voltage level sustained over a specified period of time, a voltage exceeding a threshold voltage).

In some embodiments, the barrier diode 920 can be configured to change conduction state from a voltage regulation state to a temperature-induced conduction state (e.g., a high conduction/low resistance state). When in the voltage regulation state, the barrier diode 920 can be configured to limit (e.g., clamp) a voltage across the overvoltage protection device (and a downstream load) at a threshold voltage (e.g., a voltage limit, a clamping voltage). For example, the barrier diode 920 can be configured to limit a voltage across the barrier diode 920 at a zener breakdown voltage when in the voltage regulation state. When in the temperature-induced conduction state, the barrier diode 920 may be in a thermally induced temperature-induced conduction state. In some embodiments, the temperature-induced conduction state can be a mode of the device where temperature causes secondary breakdown in the barrier diode 920 and conduction across the PN junction of the barrier diode 920. In other words, the barrier diode 920 can be configured to change from the voltage regulation state to the temperature-induced conduction state in response to a temperature of the barrier diode 920 increasing beyond a secondary breakdown temperature of the barrier diode 920. The secondary breakdown of the barrier diode 920 is different from diffusion breakdown where migration of metals across a PN junction of the overvoltage protection device in response to a temperature above a threshold temperature of the overvoltage protection device can result in a short within the overvoltage protection device (e.g., across the PN junction). Such shorting can be prevented, or substantially prevented, by a refractory layer (e.g., a diffusion barrier) within the barrier diode 920.

In some embodiments, once the barrier diode 920 has changed to the temperature-induced conduction state, the barrier diode 920 may reversibly (e.g., resettably) change back to the voltage regulation state. In other words, a change to the temperature-induced conduction state from the voltage regulation state can be a reversible change (e.g., physical change).

Accordingly, a voltage output from the power supply 930 (and across the barrier diode 920) can be changed when the voltage output exceeds a threshold voltage while the barrier diode 920 is in the voltage regulation state, or if the temperature of the barrier diode 920 exceeds a secondary breakdown temperature and the barrier diode 920 changes to the temperature-induced conduction state. For example, the barrier diode 920 can be configured to limit a voltage from the power supply 930 (and across the barrier diode 920) when the voltage output exceeds a threshold voltage (while the barrier diode 920 is in a voltage regulation state). In some embodiments, after an overvoltage condition has ended, the voltage will no longer be limited by the barrier diode 920 (because the voltage across the barrier diode 920 will be below the threshold voltage). As another example, the barrier diode 920 can be configured to increase in temperature causing a limit in a voltage output from a power supply (and across the barrier diode 920) when the voltage output exceeds a second breakdown temperature and the barrier diode 920 changes to the temperature-induced conduction state. In some embodiments, the barrier diode 920 can be referred to as changing to a high conduction state when limiting the voltage output from the power supply 930 when changing to the temperature-induced conduction state.

In some embodiments, the barrier diode 920 of the input power protection device 900 can be, or can include, for example, any type of transient voltage suppressor (TVS) (also can be referred to as a transient voltage suppression device) such as a schottkey diode, zener diode, and/or so forth. In some embodiments, the barrier diode 920 of the input power protection device 900 can be, or can include, for example, any type of device configured to change between a voltage regulation state (in response to voltage changes) and a temperature-induced conduction state (in response to temperature changes). In some embodiments, the barrier diode 920 can be configured to reversibly or irreversibly change between the voltage regulation state and the temperature-induced conduction state. In some embodiments, the barrier diode 920 of the input power protection device 900 can include one or more zener diodes, and/or so forth.

The overcurrent protection portion 910 of the input power protection device 900 can be configured to protect a load from, for example, sudden or sustained increases in current produced by a power supply. In other words, the overcurrent protection portion 910 of the input power protection device 900 can be configured to provide current protection to the load in response to, for example, an overcurrent event. In some embodiments, the overcurrent protection portion 910 of the input power protection device 900 can be configured to protect the load from current produced by the power supply based on one or more current conditions (e.g., a current level sustained over a specified period of time, a current exceeding a threshold voltage, a short high current pulse). In some embodiments, the overcurrent protection portion 910 can be configured to change conduction state from a high conduction state (e.g., a low resistive state) to a low conduction state (e.g., a high resistance state that prevents or limits (significantly limits) current from flowing to the load when a current output from the power supply (and through the overcurrent protection portion 910) exceeds a threshold current.

For example, if the overcurrent protection portion 910 is a fuse, the over current protection portion 910 can be configured to cause an open circuit (e.g., melt to produce an open circuit, blow open to produce an open circuit) that prevents current from flowing to the load when a current output from the power supply (and through the overcurrent protection portion 910) exceeds a threshold current. In some embodiments, the overcurrent protection portion 910, if a fuse, can be referred to as failing open when limiting the current output from the power supply as described. Once the fuse has failed open, the fuse may not be reset to a high conduction state. As another example, if the overcurrent protection portion 910 is resettable overcurrent protection device such as a PTC device (e.g., a PPTC device), the overcurrent protection portion 910 can be configured to change from a high conduction state to a low conduction state and limit current flowing to a load when a current output from the power supply (and through the overcurrent protection portion 910) exceeds a threshold current. In some embodiments, the overcurrent protection portion 910, if a resettable overcurrent protection device, can be referred to as being in a tripped state when limiting the current output from the power supply as described. In some embodiments, after an overcurrent condition has ended, the overcurrent protection portion 910, if a resettable overcurrent protection device, can be configured to change conduction state from the low conduction state (e.g., the high resistance state) to the high conduction state (e.g., the low resistance state).

The overcurrent protection portion 910 can be configured to change between the high conduction states and the low conduction state at a threshold temperature. In other words, the overcurrent protection portion 910 can be configured to achieve current foldback. In some embodiments, the threshold temperature can be achieved in response to a specified current flowing through the overcurrent protection portion 910 for a specified period of time.

If the overcurrent protection portion 910 is a fuse, once the fuse has changed from the high conduction state to the low conduction state at (or exceeding) the threshold temperature, the fuse may not be reset back to the high conduction state (even when the temperature of the fuse falls below the threshold temperature). In some embodiments, the fuse can include a fuse element configured to fail open (e.g., melt open) at the threshold temperature. In some embodiments, the threshold temperature of the fuse can be between 100° C. and 1000° C. In some embodiments, the threshold temperature of the fuse may be referred to as a fuse temperature,

If the overprotection portion 910 is a resettable overcurrent protection device such as a PTC device (e.g., PPTC device), once the resettable overcurrent protection device is changed from the high conduction state to the low conduction state at (or exceeding) the threshold temperature, the resettable overcurrent protection device may be reset back to the high conduction state in response to the temperature of the resettable overcurrent protection device falling below the threshold temperature. The resettable overcurrent protection device can be configured to as transitioning between the high conduction state and low conduction state. When the resettable overcurrent protection device changes from the high conduction state to the low conduction state, the resettable overcurrent protection device can be referred to as tripping, or as changing to a tripped state. When the resettable overcurrent protection device changes back to the low conduction state from the high conduction state, the resettable overcurrent protection device can be referred to as resetting, or as changing to a reset state. In some embodiments, the threshold temperature of the resettable overcurrent protection device can be between 50° C. and 300° C. In some embodiments, the threshold temperature of the resettable overcurrent protection device can be referred to as the resettable temperature.

In some embodiments, the overcurrent protection portion 910 of the input power protection device 900 can be, or can include, any type of overcurrent protection device. In some embodiments, the overcurrent protection portion 910 of the input power protection device 900 can be, or can include, for example, any type of device configured to change between conduction states (e.g., from the high conduction state to the low conduction state). In other words, the overcurrent protection portion 910 can include any type of current sensitive switch device that responds to increased current draw by switching to a low conduction state (e.g., a high resistance state). In some embodiments, the overcurrent protection portion 910 of the input power protection device 900 can be, or can include, for example, a fuse, a silicon current limit switch, a polysilicon-based fuse, an electronic fuse (e-fuse), a polymer positive temperature coefficient (PPTC) device, a ceramic positive temperature coefficient (CPTC) device, and/or so forth. In some embodiments, the barrier diode 920 can be combined with any type of overcurrent protection portion 910 that can be a resettable current limiting device that folds back current in response to increased current levels and/or temperature. In some embodiments, the input power protection device 900 can be referred to as a fusing diode.

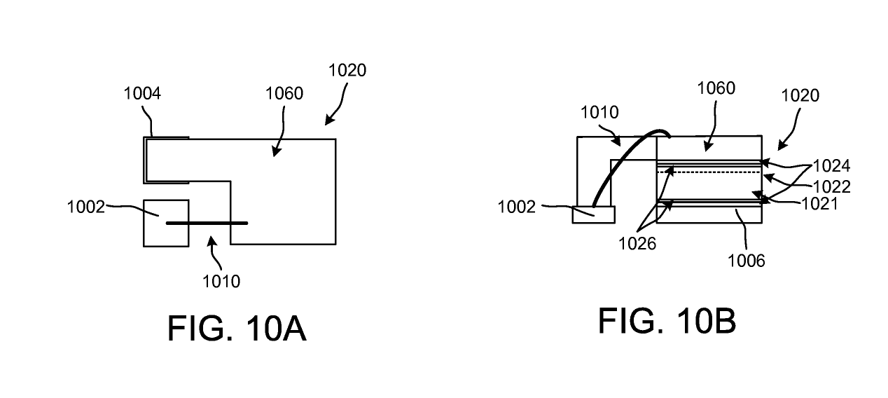

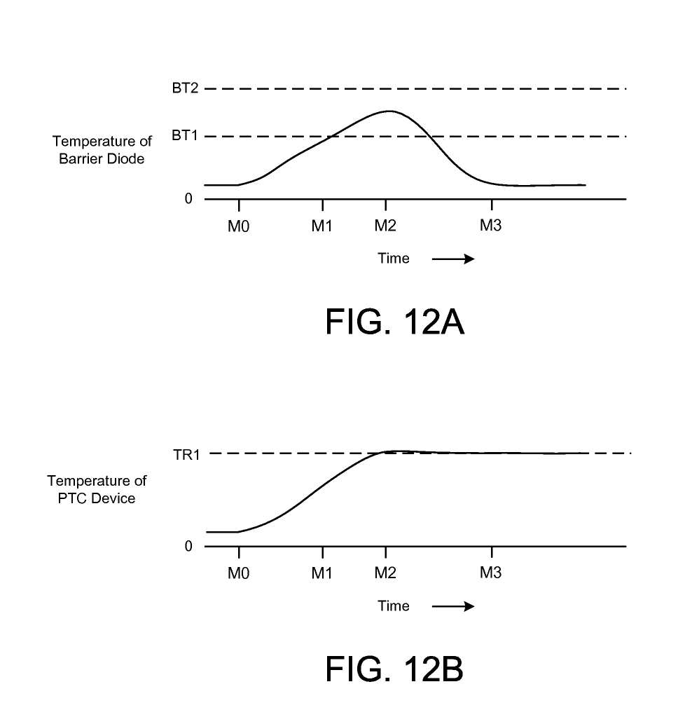

In this embodiment, the overcurrent protection portion 910 and the barrier diode 920 can be integrated into the input power protection device 900 so that the input power protection device 900 is a single integrated component (e.g., single discrete component). In other words, the input power protection device 900 is a single integrated component that includes both the overcurrent protection portion 910 and the barrier diode 920. Specifically, the overcurrent protection portion 910 and the barrier diode 920 are integrated into a single package of the input power protection device 900 with three terminals—the input terminal 902, the output terminal 904, and a ground terminal 906 (which can collectively be referred to as terminals). In some embodiments, the terminals can be referred to as ports, pins, portions, tabs, and/or so forth (e.g., input port 902 can be referred to input pin 902 or as input portion 902). Examples of physical characteristics of input power protection devices that are discrete components with both an overvoltage protection portion and an overcurrent protection portion are described, for example, in connection with FIGS. 10A, 10B, 12A, and 12B.

As shown in FIG. 9, the input power protection device 900, the power supply, and the load can be included in (e.g., integrated into) a computing device (not shown). In some embodiments, the computing device can be, for example, a computer, a personal digital assistant (PDA), a host computer, an electronic measurement device, a data analysis device, a cell phone, an electronic device, and/or so forth.

Because the overcurrent protection portion 910 and the barrier diode 920 are integrated into a single component, assembly can be simplified and can result in reduced production costs. In some embodiments, the overcurrent protection portion 910 and the barrier diode 920 are integrated into a single component (i.e., the input power protection device 900) so that installation of a separate overcurrent protection device and overvoltage protection device into an electronic assembly such as a computing device may not be necessary. Instead, overcurrent protection and overvoltage protection can be provided by the input power protection device 900, which includes both the overcurrent protection portion 910 and the barrier diode 920. In some embodiments, circuit board space can be more efficiently allocated by using the input power protection device 900, which is a single component, than if overcurrent protection and overvoltage protection were achieved using multiple separate components.

In some embodiments, because the overcurrent protection portion 910 and the barrier diode 920 are integrated into the input power protection device 900, the overcurrent protection portion 910 and the barrier diode 920 can be configured to interoperate (e.g., can be matched) in a desirable fashion. Specifically, the overcurrent detection portion 910 and the barrier diode 920 can be configured (e.g., sized) so that the overvoltage conditions and the overcurrent conditions collectively operate in a desirable fashion. For example, the barrier diode 920 can be configured so that the barrier diode 920 may not cause the overcurrent protection portion 910 to, for example, prematurely change to a low conduction state (e.g., change to high resistance state, fail open, tripped state, blow open, melt to produce an open circuit). If not properly matched, an overvoltage protection device can change to a temperature-induced conduction state and can cause an overcurrent protection device (which is separate from the overvoltage protection device) to change to a low conduction state (e.g., fail open, tripped state, high resistance state) at a fault condition, that without barrier diode temperature-induced conduction, would have kept current below a threshold current of the overcurrent protection device.

In some embodiments, integration of the overcurrent protection portion 910 and the barrier diode 920 into a single, discrete component can result in a reduced risk of undesirable barrier diode 920 open failure modes (which can then result in undesirable damage to the load 940 and/or a fire). For example, if the barrier diode 920 is not properly matched to the overcurrent protection portion 910, the barrier diode 920 (rather than the overcurrent protection portion 910) may fail open and, consequently, a voltage across the load 940 may not be appropriately limited.

As described above, the overcurrent protection portion 910 and the barrier diode 920 can each be configured to independently provide power protection. For example, the overcurrent protection portion 910 can be configured to provide overcurrent protection in response to an overcurrent event, and the barrier diode 920 can be configured to provide overvoltage protection in response to an overvoltage event. In some embodiments, because the overcurrent protection portion 910 and the barrier diode 920 are integrated into the input power protection device 900, thermal coupling (represented by the dashed double-sided arrow) between the overcurrent protection portion 910 and the barrier diode 920 can also be used to provide power protection (e.g., overcurrent protection, overvoltage protection) to a load. Specifically, the thermal coupling can be a mechanism through which the overcurrent protection portion 910 and the barrier diode 920 can interact (e.g., interoperate) to provide power protection to the load. In some embodiments, such thermal coupling may not be possible if the overcurrent protection portion 910 and the barrier diode 920 are not integrated as a single component in the input power protection device 900.

For example, heat produced by the overcurrent protection portion 910, while drawing an undesirable level of current, can be transferred to the barrier diode 920. The heat transferred to the barrier diode 920 can cause the barrier diode 920 to change from a voltage regulation state to a temperature-induced conduction state (e.g., low resistivity state) and thereby increase draw current through the overcurrent protection portion 910. The current drawn through the overcurrent protection portion 910, in response to the current drawn through the barrier diode 920, can cause the overcurrent protection portion 910 to change to a low conduction state (e.g., fail open, tripped state, a high resistivity state) and protect a load coupled to the output terminal 904 from an undesirable level of current and limit the heat that the overcurrent protection portion 910 can transfer to a board. Thus, when the barrier diode 920 is thermally coupled to the overcurrent protection portion 910, the overcurrent protection portion 910 can be configured to heat the barrier diode 920 to its critical thermal break down temp (which can be, by design, lower than the overcurrent protection portion 910 element open temp), the barrier diode 920 will changed to a temperature-induced conduction state, pull more current through the overcurrent protection portion 910, and cause the overcurrent protection portion 910 to change to a low conductions state. In some embodiments, the temperature at which the overcurrent protection portion 910 changes to a low conduction state (e.g., a fail open state) can be higher than the secondary breakdown temperature of the barrier diode 920. In some embodiments, the voltage foldback (or secondary breakdown) that occurs at (or above) the secondary breakdown temperature of the barrier diode 920 can cause an increase in temperature in the overcurrent protection portion 910 and accelerated failing open (change in state) of the overcurrent protection portion 910 such that the total amount of energy the barrier diode 910 absorbs prior to the overcurrent device opening is reduced.

In some thermally decoupled systems using multiple separate components (and, in particular, systems using a fuse without a barrier diode), relatively low currents near the threshold current (e.g., rated current, open current) of the overcurrent protection portion 910 can increase the overcurrent protection portion 910 temperature and related board temperature to dangerous (e.g., damaging) levels, without causing the overcurrent protection portion 910 to change to a low conduction state. If the overcurrent protection portion 910 is, or includes, a fuse, the fuse can achieve very high temperature when running near the threshold current—this can result in a board fire in some systems.

As another example, in some embodiments, the secondary breakdown temperature of the barrier diode 920 can be relatively high (e.g., higher than a diffusion breakdown temperature) so that the barrier diode 920 does not change from a voltage regulation state to a temperature-induced conduction state (e.g., low resistivity state) before the overcurrent protection portion 910, which can be a resettable overcurrent protection device, transitions from the high conduction state low to the conduction state. If the input power protection device 900 included, for example, a zener diode (without a refractory metal layer) instead of the barrier diode 920, the zener diode may fail short (e.g., fail short at the diffusion breakdown temperature) before the overcurrent protection portion 910 transitions from the high conduction state to the low conduction state. In such embodiments, the power handling of the input power protection device 900 would be limited by the power handling of the zener diode (and the relatively low temperature of the diffusion breakdown temperature compared with the relatively high temperature of the secondary breakdown temperature) which may cause the overcurrent protection portion 910 to transition (e.g., prematurely transition). Thus, the input power protection device 900 can be configured to handle more power with use of the barrier diode 920 than would be possible if using a typical zener diode. Moreover, the input power protection device 900 can be configured to handle more power by using the barrier diode 920 than by using a zener diode that has approximately the same size (e.g., foot print, PN junction real estate) as the barrier diode 920 because of the difference in temperature at which each of these devices experience crowbar breakdown. In such embodiments, the power handling of the input power protection device 900 would not be diode limited.

In some embodiments, current through the barrier diode 920 can cause the barrier diode 920 to transfer heat (via thermal coupling) from the barrier diode 920 to the overcurrent protection device 910. The heat transferred to the resettable overcurrent protection device can cause the overcurrent projection device 922 change from a high conduction state (e.g., a low resistance state, a reset state) to a low conduction state (e.g., a high resistance state, a tripped state) faster than would be possible without the heat transferred from the barrier diode 920. Thus, thermal coupling between the barrier diode 920 and the resettable overcurrent protection device can contribute to the resettable overcurrent protection device changing from the high conduction state low conduction state (i.e., contribute to tripping of the resettable overcurrent protection device). In some embodiments, the barrier diode 920 can have a relatively high secondary breakdown temperature so that heat (via thermal coupling) from the barrier diode 920 continues to be transferred to the overcurrent protection device 910 to contribute to the overcurrent protection device 910 changing to a low conduction state (e.g., high resistance state, a tripped state) before secondary breakdown within the barrier diode 920 occurs. Thus, the relatively high secondary breakdown temperature of the barrier diode 920 allows for more heat transfer from the barrier diode 920 (before breakdown) to the overcurrent protection device 910 to contribute to the overcurrent protection device 910 changing to a low conduction state (e.g., high resistance state, a tripped state) than would be possible with a relatively low breakdown at the diffusion breakdown temperature. In other words, heat transferred from the barrier diode 920 to the overcurrent protection portion 910 can accelerate changing of the overcurrent protection portion 910 from the high conduction state low conduction state.

As yet another example, in some embodiments, the barrier diode 920 can also be configured so that the barrier diode 920 changes from a voltage regulation state to a temperature-induced conduction state before the overcurrent protection portion 910 (e.g., resettable overcurrent protection device) reaches a temperature that would cause the overcurrent protection portion 910 to change from a high conduction state to a low conduction state. Specifically, if the secondary breakdown temperature of the barrier diode 920 is relatively low (e.g., at or around the diffusion breakdown temperature), the barrier diode 920 may change from a voltage regulation state to a temperature-induced conduction state (e.g., low resistivity state) before the overcurrent protection portion 910 reaches a temperature that would cause the overcurrent protection portion 910 to transition from the high conduction state to the low conduction state. In such embodiments, in response to the barrier diode 920 changing to the temperature-induced conduction state, the barrier diode 920 can source an increased current and can drive (e.g., draw, pull) an increased current through the overcurrent protection portion 910. The increased current through the overcurrent protection portion 910 can cause the overcurrent protection portion 910 to increase rapidly in temperature (through I²R heating). In some embodiments, the increase in current through the overcurrent protection portion 910 driven by the barrier diode 920 changing to the temperature-induced conduction state, in conjunction with heat transferred from the barrier diode 920, can cause the overcurrent protection portion 910 to change to the low conduction state faster than would be possible had the barrier diode 920 not changed to the temperature-induced conduction state or in the absence of thermal coupling between the barrier diode 920 and the overcurrent protection device portion 910. In other words, the barrier diode 920 can be configured to accelerate changing of the overcurrent protection portion 910 from the high conduction state low conduction state.

Because both the barrier diode 920 and the overcurrent protection portion 910 can both be configured to reversibly (e.g., resettably) change states, the barrier diode 920 and the overcurrent protection portion 910 can perform the state changes described above multiple times. Specifically, the barrier diode 920 can change from the voltage regulation state to the temperature-induced conduction state and drive an increase in current in the overcurrent protection portion 910 that causes the overcurrent protection portion 910 to change to a low conduction state (at a threshold temperature of the overcurrent protection portion 910). If the overcurrent protection portion 910 is a resettable overcurrent protection device, the overcurrent protection portion 910 can change back to the high conduction state after the temperature of the overcurrent protection portion 910 has fallen below the threshold temperature. Also, the barrier diode 920 can reversibly change back to the voltage regulation state after the temperature of the barrier diode 920 has fallen below the secondary breakdown temperature. If the input power protection device 900 included, for example, a zener diode (without a refractory metal layer) instead of the barrier diode 920, the zener diode may irreversibly (e.g., permanently) fail short (e.g., fail short at the diffusion breakdown temperature).

In some embodiments, the barrier diode 920 can be configured to change from the voltage regulation state to the temperature-induced conduction state, and can remain in the temperature-induced conduction state long enough to cause a resettable overcurrent protection device to change to a low conductions state (e.g., tripped state). The change to the low conduction state can be triggered by heating responsive to current pulled through the resettable overcurrent protection device by the barrier diode 920 while in the temperature-induced conduction state. In some embodiments, the barrier diode 920 can be configured to reversibly operate in the voltage regulation state after remaining in the temperature-induced conduction state long enough to cause the resettable overcurrent protection device to change to the low conduction state. Thus, the time during which the resettable overcurrent protection device can respond (given a particular rate of energy/power) using the barrier diode 920 is increased over what would be possible using a typical diode (having a similar junction characteristic as the barrier diode 920). The barrier diode 920 can be configured to facilitate (e.g., by remaining in the temperature-induced conduction state) or accelerate changing of the overcurrent protection portion 910 (such as a resettable overcurrent protection device) from the high conduction state low conduction state.

In some embodiments, after resettable overcurrent detection device has changed low conduction state, current through the barrier diode 920 can be reduced (e.g., substantially reduced) such that barrier diode 920 temperature decreases in the barrier diode can reversibly (e.g., substantially reversibly) change from the temperature-induced conduction state back to the voltage regulation state (without sustaining damage). In other words, after changing to low conduction state, the overcurrent protection portion 910 can be configured to accelerate changing of the barrier diode 920 back to the voltage regulation state.

In some embodiments, the secondary breakdown temperature of the barrier diode 920 that results in a temperature-induced conduction state that drives (e.g., pulls, draws) current through the overcurrent protection portion 910 can be defined using a dopant level within the barrier diode 920. In some embodiments, the doping concentration within the barrier diode 920 can be defined so that the secondary breakdown temperature of the barrier diode 920 can be at a desirable temperature for the overcurrent protection portion 910 used in conjunction with the barrier diode 920. In other words, the steady-state temperature (e.g., max steady-state temperature) at which the barrier diode 920 will achieve secondary breakdown may be defined using one or more dopant concentrations within the barrier diode 920. For example, in some embodiments, the secondary breakdown temperature of the barrier diode 920 can be at specified at a relatively high temperature using one or more dopant concentrations within the barrier diode 920 so that a temperature at which the barrier diode 920 will pull additional current through the overcurrent protection portion 910 will be higher than if the secondary breakdown temperature of the barrier diode 920 were lower. As another example, in some embodiments, the secondary breakdown temperature of the barrier diode 920 can be specified at a relatively low temperature using one or more dopant concentrations within the barrier diode 920 so that a temperature at which the barrier diode 920 will pull additional current through the overcurrent protection portion 910 will be lower than if the secondary breakdown temperature of the barrier diode 920 were higher. In such embodiments, the secondary breakdown at the relatively low secondary breakdown temperature can increase the thermal protection function of the barrier diode 920 than if the secondary breakdown temperature were higher.

In some embodiments, the barrier diode 920 can have a specified secondary breakdown temperature (via a specified dopant concentration(s) within the barrier diode 920) so that the barrier diode 920 within the input power protection device 900 will have a specified power rating at, or around, secondary breakdown of the barrier diode 920. In some embodiments, for example, the barrier diode 920 can have a relatively high secondary breakdown temperature (via increased dopant concentration(s) within the barrier diode 920) to increase a temperature (e.g., a peak temperature) before crowbar (i.e., secondary breakdown) of the barrier diode 920 and to increase the power rating of the barrier diode 920 in an input power protection device 900 over what would otherwise be achieved if the barrier diode 920 had a relatively low secondary breakdown temperature (or no barrier thereby failing short at a relatively low temperature).

In some embodiments, the use of the barrier diode 920 within the input power protection device 900 can improve the cycle life of the input power protection device 900 over an input power protection device (not shown) that, all things being equal, includes, for example, a diode (i.e., a diode without a refractory metal layer). For example, if using a typical diode (or zener diode) without a refractory metal layer (such as that included in the barrier diode 920) in the input power protection device 900 integrated with a fuse, currents below the rated current of the fuse could cause a localized in-rush current and/or localized heating of the fuse that is too low to cause the fuse to change to a low conduction state but would be high enough to cause undesirable diffusion of the fuse element and/or surrounding components (such as a metal conductor coupled to the diode). As a specific example, if the overcurrent protection portion 210 is a tin-copper fuse element, relatively small temperature excursions related to localized in-rush current and/or localized heating can exceed 300° C., (but stay below the 450° C. element melting temp of the tin-copper fuse). The relatively high temperatures can drive (at a relatively slow rate) tin diffusion into copper, which can lower the effective melting point of the fuse element and its hold current. As another example, in a silver-based fuse element, temperatures can exceed 600° C. (but stay below the 750° C. silver-based fuse element melting temp), and drive diffusion (a relatively slow rate) of silver into the surrounding glass, resulting in an increase in fuse resistance and reduction of hold current.

As another example, if using a typical diode (or zener diode) without a refractory metal layer (such as that included in the barrier diode 920) in the input power protection device 900, currents below the rated current of the overcurrent protection device (e.g., fuse) could heat the diode and cause diffusion of a metal conductor coupled to a substrate of the diode to drift into the substrate of the diode and ultimately cause a short within the diode even if the rated current (and threshold diffusion temperature) of the diode is never exceeded. In other words, without a diffusion barrier, the diode can ultimately fail short, even though rated currents and voltages (as determined on fresh devices) were never exceeded. The barrier diode 920 with the diffusion barrier will be more robust to this type of damaging diffusion (that may be caused by cycling of the fuse at currents below the rated current) than a typical diode without the diffusion barrier. Thus, a temperature stable diffusion barrier in the diode structure to form the barrier diode 920, can prevent, or substantially prevent, junction shorting and can result in an increase the cycle life performance of the input power protection device 900.

In some embodiments, a power supply coupled to the input terminal 902 can be any type of power supply such as, for example, a switched mode power supply, a direct-current (DC) power supply, an alternating-current (AC)power supply, and/or so forth. In some embodiments, the power supply can include a power source that can be any type of power source such as, for example, a direct current (DC) power source such as a battery, a fuel cell, and/or so forth.

In some embodiments, the barrier diode 920 can be configured with a relatively high secondary breakdown temperature so that the barrier diode 920 may absorb more energy prior to achieving secondary breakdown. In such embodiments, the overcurrent protection portion 910 may have more time to respond than if the second breakdown temperature of the barrier diode 920 were relatively low. In some embodiments, the barrier diode 920 can be thermally coupled with an overcurrent protection portion 910 such as a PPTC, or other thermally reactive overcurrent device, to cause a non-linear resistance response in the overcurrent protection portion 910 for improved protection of a load coupled to the input power protection device 900.

FIG. 10A is a block diagram that illustrates a top view of components of an input power protection device. FIG. 10B is a block diagram that illustrates a side view of the components of the input power protection device shown in FIG. 10A. The input power protection device 1000 includes a fuse 1010 that functions as an overcurrent protection portion and a barrier diode 1020 that functions as an overvoltage protection portion. In this embodiment, the fuse 1010 is defined by a wire that is coupled to (e.g., wire bonded to) an input terminal 1002 and coupled to (e.g., wire bonded to) a metal plate 1024 that is part of the barrier diode 1020. In other words, the fuse 1010 can be a wire bond fuse. In some embodiments, the fuse 1010 can be any type of fuse (e.g., a narrow metal structure fuse, an on-diode fuse layer).

As shown in FIG. 10A, the barrier diode 1020 can be coupled to an output terminal 1004 of the input power protection device 1000 via a conductive clip 1060. In some embodiments, the conductive clip 1060 can be made of any type of conductive material such as, for example, aluminum, gold, and/or so forth. In some embodiments, the conductive clip 1060 can be made of the same material as the fuse 1010.

The conductive clip 1060 can be configured so that the fuse 1010 will fail open before the conductive clip 1060 fails open in response to current flowing between the input terminal 1002 and the output terminal 1004 via the fuse 1010 and the conductive clip 1060. The fuse 1010 will fail open before the conductive clip 1060 fails open because the cross-sectional area (and resistance) of the fuse 1010 can be smaller than the collective cross-sectional area (and resistance) of the conductive clip 1060.

In some embodiments, use of the conductive clip 1060 can facilitate handling of relatively high pulses of energy because the conductive clip 1060 can have a relatively large mass (e.g., large surface area) coupled to, for example, the barrier diode 1020 and/or the output terminal 1004. In some embodiments, the conductive clip 1060 can have a relatively large mass that can function as a thermal sink (e.g., a thermal heat sink) for the barrier diode 1020 and/or the output terminal 1004. Thus, the barrier diode 1020 can be a higher power component than if a conductor smaller than the conductive clip 1060 were coupled to the barrier diode 1020.

As shown in FIG. 10B, the barrier diode 1020 includes a semiconductor 1021 that has a PN junction 1022. Refractory metal layers 1026 are disposed between the metal plates 1024 are disposed on top and on bottom of the semiconductor 1021. In some embodiments, the metal plates 1024 and/or refractory metal layers 1026 can be defined by metal disposed (e.g., sputtered) using semiconductor processing needs. In some embodiments, the metal plate 1024 and/or the refractory metal layers 1026 may not cover the entire top portion or bottom portion of the semiconductor 1021. As shown in FIG. 10B, the PN junction of the barrier diode 1020 is closer to the top portion of the semiconductor 1021 than the bottom portion of the semiconductor 1021. Although not shown in FIG. 10B, the PN junction of the barrier diode 1020 can be closer to the bottom portion of the semiconductor 1021 than the top portion of the semiconductor 1021.

As shown in FIG. 10B, the barrier diode 1020 is coupled directly to a ground terminal 1006 via the metal plate 1026. Although not shown in FIG. 10A or 10B, in some embodiments, the barrier diode 1020 may be coupled to the ground terminal 1006 via one or more conductors (e.g., one or more wires).

Although not shown in FIG. 10A or FIG. 10B, the components of the input power protection device shown in FIGS. 10A and 10B can be integrated into a package. In some embodiments, additional components, in addition to those mentioned above, can be included in the input power protection device.

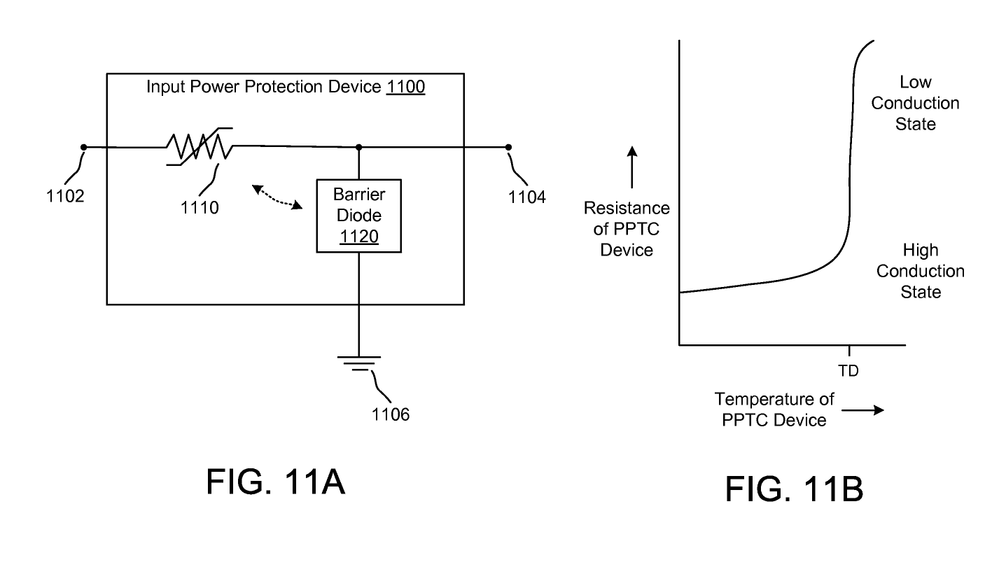

FIG. 11A is a schematic of an input power protection device 1100 including a polymer positive temperature coefficient (PPTC) device 1110 (or a PTC device) and a barrier diode 1120. As shown in FIG. 11A, the input power protection device 1100 includes the PPTC device 1110, which functions as an overcurrent protection portion of the input power protection device 1100. The input power protection device 1100 also includes the barrier diode 1120, which functions as an overvoltage protection portion (and can be referred to as an overvoltage protection portion) of the input power protection device 1100. In some embodiments, the barrier diode can be similar to any of the barrier diodes described herein.

As shown in FIG. 11A, the PPTC 1110 and the barrier diode 1120 are integrated into the input power protection device 1100 so that the input power protection device 1100 functions as a single integrated component. In other words, the PPTC 1110 and the barrier diode 1120 can be packaged into the input power protection device 1100 so that the input power protection device 1100 functions as a standalone discrete component.

Because the PPTC 1110 and the barrier diode 1120 are integrated into the input power protection device 1100, the input power protection device 1100 includes three terminals. As shown in FIG. 11A, the three terminals of the input power protection device 1100 are an input terminal 1102, an output terminal 1104, and a ground terminal 1106. As shown in FIG. 11A, the input terminal 1102 is coupled to (e.g., electrically coupled to) an end of the PPTC 1110. The barrier diode 1120 is coupled to (e.g., electrically coupled to) an end of the PPTC 1110, which is also coupled to (e.g., electrically coupled to) the output terminal 1104. Thus, the end of PPTC 1110 and the barrier diode 1120 are both coupled to the output terminal 1104 and function as a single node. The barrier diode 1120 is also coupled to the ground terminal 1106.

Because the input power protection device 1100 includes a three terminal architecture, the PPTC 1110 can change to a low conduction state (also can be referred to as a tripped state) and interrupt (e.g., limit) current to both the barrier diode 1120 and a downstream system (e.g., a load) coupled to the input power protection device 1100 via the output terminal 1104. In some embodiments, the PPTC 1110 can between a high conduction state and a low conduction state in response to a change in temperature of the PPTC 1110. For example, the PPTC 1110 can change from a high conduction state to the low conduction state in response to an increase in temperature of the PPTC 1110. The PPTC 1110 can change back to the low conduction state from the high conduction state in response to a decrease in temperature of the PPTC 1110.

FIG. 11B is a graph that illustrates the behavior of the PPTC 1110 shown in FIG. 11A. A resistance of the PPTC device is shown along the y-axis, and a temperature the PPTC device is shown along the x-axis. As shown in FIG. 11B, at relatively low temperatures of the PPTC device the resistance of the PPTC device is also relatively low. As the temperature of the PPTC device increases, the resistance of the PPTC device also increases at a relatively steady rate until at approximately temperature TD, the resistance of the PPTC device increases dramatically. At approximately the temperature TD, the PPTC device changes from the high conduction state to the low conduction state to cause or substantially cause an open circuit. Said differently, at approximately the temperature TD the PPTC 1110 can be configured to thermally transition to the low conduction state. The temperature TD, in some embodiments, can be referred to as a threshold temperature of the PPTC device.

Referring back to FIG. 11A, in some embodiments, the PPTC 1110 can change to the low conduction state in response to a downstream overcurrent event, an overvoltage event, and/or a thermal coupling mechanism with the barrier diode 1120. Thus, the functionality of the input power protection device 1100 can be the same as, or similar to, the functionality of the input power protection device 900 described in connection with FIG. 9.

For example, secondary breakdown (or voltage foldback) of the barrier diode 1120 can be leveraged to increase current through the PPTC device 1110 to accelerate the current limit event (change in state from a high conduction state to a low conduction state) of the PPTC device 1110, which can result in an improved PPTC device 1110 response time and protection of a downstream load. In such embodiments, barrier diode 1120 foldback (or secondary breakdown) at the secondary breakdown temperature and absorption of power by the barrier diode 1120 can be leveraged so that the PPTC device 1110 has sufficient time to change from a high conduction state to a low conduction state. In some embodiments, heat transferred to the PPTC device 1110 from the barrier diode 1120 can be leveraged to accelerate the PPTC device 1110 tripping (i.e., changing from the high conduction state to the low conductions state). In some embodiments, thermal coupling between the PPTC device 1110 and the barrier diode 1120 can be leveraged to assure the PPTC device 1110 does not change (e.g., does not reset) from the low conduction state (after being changed from the high conduction state) until the barrier 1120 diode cools off (via conduction and/or convection) below the secondary breakdown temperature.

In some embodiments, the use of the barrier diode 1120 can increase the operating temperature of the input power protection device 1100 over two times what would be possible using, for example, a zener diode. In some embodiments, the operating temperature of the input power protection device 1100 can be less than or equal to two times what would be possible using, for example, a zener diode. In some embodiments, the use of the barrier diode 1120 can increase the operating window of the PPTC 1110 over eight times what would be possible using, for example, a zener diode. In some embodiments, the resettable thermal voltage foldback of the barrier diode 1120 and high failure temperature can be used to increase the power handling capability of the input power protection device 1100 by approximately 10 times or more (e.g., 10 times a 40 watt (W) device that includes a 1.2 amp (A) I-hold (hold current) PPTC, 10 times a 30 W device that includes a 2.3 A I-hold PPTC) than the power handling that would be possible using, for example, a zener diode. In some embodiments, the power handling capability of the input power protection device 1100 using the barrier diode 1120 can be less than 10 times the power handling that would be possible using, for example, a zener diode.

As a specific example, a PPTC device with no thermal coupling (in contrast to FIG. 11A) may have an I-hold maximum of approximately 0.25 amps (A). A zener diode (which is not thermally coupled to the PPTC device) may have a breakdown voltage of 10 V with a 2.24 mm² die size and 5 Watt rating. The power rating of the zener diode can be defined, in part, by the diffusion breakdown temperature. The maximum steady state current for the device would be 0.5 A (5 W at 10 V). Accordingly, the trip current (I-trip) of the PPTC device would have to be below 0.5 A, and the hold current (I-hold) of the PPTC device must be below 0.25 A. This particular configuration may not be practical in many applications because of the limited current levels of 0.5 A and 0.25 A.

The solution above is contrasted with the integrated PPTC device 1110 and barrier diode 1120 shown in FIG. 11A. The barrier diode 1120, similar to the device above, may have a breakdown voltage of 10 V with a 2.24 mm² die size, but can have a higher power rating because of the refractory metal layer that allows for secondary breakdown at a temperature that is much higher than the diffusion temperature. For example, the power rating of the barrier diode 1120 can be approximately 10 W, which is twice as high as the power rating of the zener diode described above based on a proportional increase in breakdown temperature of the barrier diode 1120 over the zener diode. Specifically, the power rating of the barrier diode 1120 can be twice as high as a power rating of the zener diode because secondary breakdown temperature can be twice as high as the diffusion temperature of the zener diode. Accordingly, with the foldback capabilities of the barrier diode 1120 at the secondary breakdown temperature, the trip current (I-trip) of the PPTC device 1120 can be as high as 10 amps at 1 V (for a limited period of time) and the hold current (I-hold) can be as high as 5 A.

FIGS. 12A and 12B are graphs that illustrate operation of an input power protection device. FIGS. 12A and 12B can illustrate the operation of an input power protection device such as the input power protection device 1100 (which may or may be integrated into a single component) described in connection with FIGS. 11A and 11B. In FIGS. 12A and 12B, time is increasing to the right. FIG. 12A is a diagram that illustrates temperature of a barrier diode within an input power protection device, and FIG. 12B is a diagram that illustrates temperature of the PTC device within the input power protection device.

As shown in FIGS. 12A and 12B, the temperature of the barrier diode and the temperature of the PTC device, respectively, can increase starting at approximately time MO in response to a fault event (e.g., an overvoltage event and/or an overcurrent event). Thermal coupling (e.g., heat transferred) from the PTC device to the barrier diode, and vice versa, can cause the temperature of the PTC device and the temperature of the barrier diode to increase.

As shown in FIG. 12B, when the temperature of the PTC device reaches the threshold temperature TR1 (e.g., trip temperature) of the PTC device at approximately time M2, the PTC device changes from a high conduction state to a low conduction state. The change in conduction state cuts off, or limits, current through the PTC device and through the barrier diode. As shown in FIG. 12A, in response to the decrease in current, the temperature of the barrier diode starts to drop starting at approximately time M2 until the temperature of the barrier diode reaches a steady state temperature approximately time M3. In this embodiment, the temperature of the PTC device reaches the threshold temperature TR1 and changes to the low conduction to limit current through the barrier diode so that the temperature of the barrier diode is decreased before the barrier diode reaches the secondary temperature BT2.

As shown in FIG. 12 A, in this embodiment, the temperature of the barrier diode exceeds the threshold diffusion temperature BT1 of the barrier diode without breaking down (e.g., folding back) because the barrier diode includes a refractory metal layer that prevents, or substantially prevents diffusion breakdown. If the barrier diode were a typical diode without the refractory metal layer, the diode could undergo irreversible diffusion breakdown at the threshold diffusion temperature, and could pull current through the PTC device so that the PTC device trips at approximately time M1 (rather than at time M2). In such instances, the operating window of the input power protection device would be limited by the breakdown of the barrier diode at the threshold diffusion temperature.

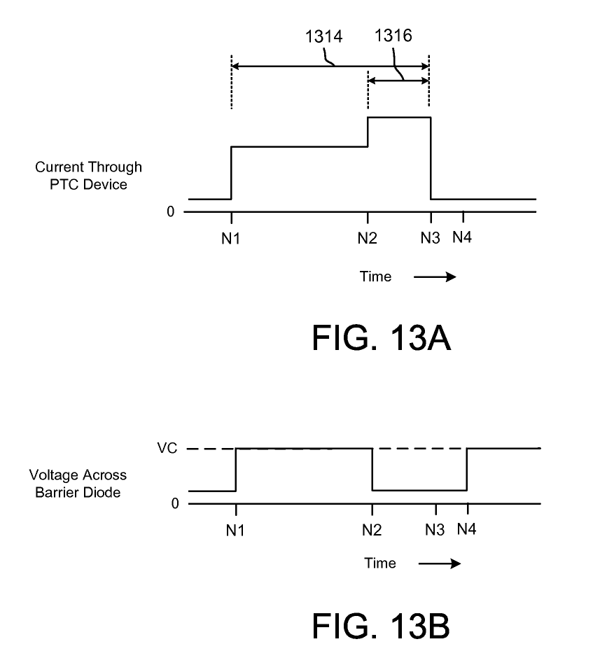

FIGS. 13A and 13B are also graphs that illustrate operation of an input power protection device. FIGS. 13A and 13B can illustrate the operation of an input power protection device such as the input power protection device 1100 (which may or may be integrated into a single component) described in connection with FIGS. 11A and 11B. In FIGS. 13A and 13B, time is increasing to the right. FIG. 13A is a diagram that illustrates current through a PTC device, and FIG. 13B is a diagram that illustrates voltage across a barrier diode.

As shown in FIGS. 13A and 13B, the current through the PTC device and the voltage across the barrier diode, respectively, increase starting at approximately time N1 in response to a fault event (e.g., an overvoltage event and/or an overcurrent event). As shown in FIG. 13A, the voltage across the barrier diode is clamped at the clamping voltage VC (or regulation voltage VC). Although not shown in FIGS. 13A and 13B, the temperature of the barrier diode increases between times N1 and N2 in response to the fault event until the temperature of the barrier diode increases beyond the secondary breakdown temperature and, as shown in FIG. 13B, the barrier diode changes from a voltage regulation state to a temperature-induced conduction state at time N2 and the voltage across the barrier diode drops. In response to the barrier diode changing to the temperature-induced conduction state, current through the PTC device increases at approximately time N2 as shown in FIG. 13A. Although not shown in FIGS. 13A and 13B, the temperature of the PTC device increases between times N2 and N3 in response to the increase in current until, as shown in FIG. 13A, the PTC device is tripped at time N3 and changes from a high conduction state to a low conduction state at time N3 and current through the PTC drops.

In response to the change from the high conduction state low conduction state at time N3 current through the barrier diode is decreased so that the temperature (not shown) of the barrier diode decreases between times N3 and N4. In response to the temperature of the barrier diode decreasing below the second breakdown temperature, the barrier diode changes from the temperature-induced conduction state back to the voltage regulation state as represented by the increase in voltage across the barrier diode to the clamping voltage.

In some embodiments, thermal coupling (e.g., heat transferred) from the PTC device to the barrier diode, and vice versa, can cause the temperature of the PTC device and the temperature of the barrier diode to increase at a faster rate than without thermal coupling (e.g., thermal coupling within an integrated device). In such embodiments, the barrier diode can change from the voltage regulation state to the temperature-induced conduction state earlier than time N2. Also, in such embodiments, the PTC device can change from the high conduction state to the low conduction state earlier than time N3. Thus, the time period 1314 and/or the time period 1316 can be decreased.

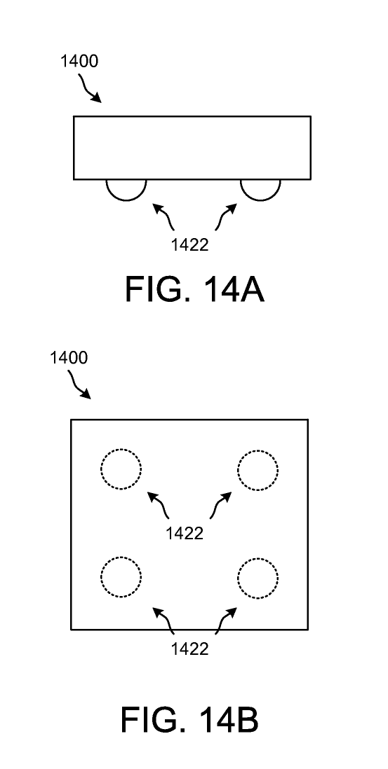

FIG. 14A is a side view of an input power protection device 1400, according to an embodiment. As shown in FIG. 14A, the input power protection device 1400 is implemented as a chip-scale package (CSP) device. In some embodiments, the chip-scale package device can be referred to as a chip-size packaging device. In some embodiments, the input power protection device 1400 is less than or equal to 1.5 times the size of the die of an overvoltage protection portion (e.g., a zener diode) of the input power protection device 1400. In some embodiments, the input power protection device 1400 is greater than 1.5 times the size of the die of an overvoltage protection portion (e.g., a zener diode) of the input power protection device 1400. As shown in FIG. 14A, the input power protection device 1400 has pads or balls (e.g., a ball grid array (BGA)) 1422 that can be used to couple the input power protection device 1400 to for example, a board (e.g., a PCB). In some embodiments, the input power protection device 1400 can be implemented as a wafer level chip scale package (WL-CSP). Although not shown in FIG. 14A, a barrier diode (alone) can be implemented as a CSP such as that show in FIG. 14A.

FIG. 14B is a top view of the input power protection device 1400 shown in FIG. 14A, according to an embodiment. As shown in FIG. 14B the input power protection device 1400 has four pads 1422. In some embodiments, the input power protection device 1400 can have more or less pads 1422 than are shown in FIG. 14B. In some embodiments, one or more of the pads 1422 can include, or can be, an input terminal, an output terminal, and/or a ground terminal.

Any of the embodiments described herein can be implemented in a CSP device. For example, the input power protection device shown in FIGS. 10A and 10B can be implemented as a CSP device. In such embodiments, wire bonds, clips, and/or wire routing can be replaced with balls and/or can be implemented using silicon processing structures.

Implementations of the various techniques described herein may be implemented in electronic circuitry, on electronic circuit boards, in discrete components, in connectors, in modules, in electromechanical structures, or in combinations of them. Portions of methods also may be performed by, and an apparatus may be implemented as, or integrated into special purpose semiconductor circuitry, e.g., an FPGA (field programmable gate array) or an ASIC (application-specific integrated circuit).

Implementations may be implemented in an electrical system that including computers, automotive electronics, industrial electronics, portable electronics, telecom systems, mobile devices, and/or consumer electronics. Components may be interconnected by any form or medium of electronic communication, e.g., a communication network. Examples of communication networks include a local area network (LAN) and a wide area network (WAN), e.g., the Internet.

In some embodiments, a refractory metal barrier (or other diffusion barrier) on a TVS or Zener diode can be used between the silicon and other metal plating to change the failure mode and extend diode transient performance. In some embodiments, aluminum silicon diffusion under high peak temperatures can be prevented (or substantially prevented), thereby changing the mode of failure. In some embodiments, the voltage fold back (breakdown) mechanism can be changed from permanent aluminum diffusion (around 300-400 C), to thermally induced secondary breakdown (carrier density dependent from 100 to 600 C) increasing the potential for surviving a breakdown event. In some embodiments, the reversibility of secondary breakdown events can be leveraged to enhance transient and overvoltage energy absorption capabilities of the device. In some embodiments, the breakdown temperature can be raised in order to enhance transient and overvoltage energy absorption capabilities. In some embodiments, the breakdown temperature can be lowered to offer improved thermal protection.

In some embodiments, diffusion barrier metals and associated high temp failure points can be used, in conjunction with lower doping levels to reduce the secondary breakdown temperature below what is common in aluminum to silicon diodes to enhance protection and increase device survivability in secondary breakdown. In some embodiments, lower secondary breakdown temperatures can be used to crowbar the diode at lower steady state temperatures. In some embodiments, lower secondary breakdown temperatures can be used to crowbar the diode at temperatures low enough to prevent the diode from falling off the board in an over voltage event. In some embodiments, lower breakdown temperature can be used as a way to increase the survivability time of the device in secondary breakdown. In some embodiments, permanent failure can occur once a critical temperature is attained at the hottest point of the die. This hot spot can be typically at the point where secondary breakdown occurs, as the local voltage fold back generates high current concentrations. Reducing the secondary breakdown temp can allow for more time for heat to spread from the initial breakdown location, and generate a larger breakdown zone, thereby reducing current density of the hot spot, and increasing the time it takes to achieve a critical failure temperature. In some embodiments, a lower breakdown temperatures controlled by doping can be used, with barrier metals, to further increase the survivability time of the device in secondary breakdown. Barrier metals can be used to increase the critical failure temperature of the device.

In some embodiments, the thermally induced secondary breakdown, refractory metal diffusion barriers and thermal mass can be used, to create a simple single two pin device, equivalent to (or approximately equivalent to) an integrated clamping device and a time delayed thyristor or SCR device with timing circuit. In such embodiments, voltage fold back function can be changed to be temperature driven (versus voltage driven as in an SCR). In some embodiments, thermal properties such as thermal mass, heat sinks, die thinning can be used versus electric fields and circuit design elements to control fold-back timing. In some embodiments, a reduced pin count SCR (no gate) can be achieved. In some embodiments, a device that returns to normal (high resistance/primary breakdown point) by reducing device temperature (versus gate current as in a traditional SCR). In some embodiments, SCR like latching function by driving current through the device can be achieved by leverages a thermal I²R mechanism versus current injection to maintain its latch.

In some embodiments, barrier diodes can be combined with a PTC or other resettable current limiting device that folds back current in response to increased current levels or temperature. In some embodiments, higher failure temperatures and/or longer secondary breakdown fold back survivability can be used to allow the die to absorb more energy prior to failure, giving more time for the over current device to respond. In some embodiments, thermally coupling a higher pulse temperature capable diode with a PPTC or other thermally reactive over current device and leveraging higher operating temperatures to drive a non-linear resistance jump in the OC device to improving system protection. In some embodiments, the Voltage fold back that occurs at the secondary breakdown temperature can be used to increase PTC current and accelerate the trip event of the PTC, thereby reducing the total amount of energy the diode may absorb prior to PTC trip.

In some embodiments, barrier diode and secondary breakdown technology can be used with a PPTC to create a higher power PolyZen Device. In some embodiments, higher barrier diode survival temperatures can be leveraged to increase and drive faster thermal transfer between the diode and the PPTC—thereby improving PPTC response time and protection levels. In some embodiments, barrier diode voltage fold back at the secondary breakdown temperature can be leveraged to increase PPTC current and accelerate the current limit event of the PPTC, thereby improving PPTC response time and protection levels. In some embodiments, barrier diode voltage fold back at the secondary breakdown temperature can leverage diode power absorption, thereby giving the PPTC more time to switch. In some embodiments, the thermal coupling between the PPTC and barrier diode can be leveraged to assure the PPTC does not exit its tripped state until the diode cools off below its critical temperature the secondary breakdown temperature.

In some embodiments, the technology described above can be used with any other over current protection device, either integrated or in discrete form. In some embodiments, thermally coupling the barrier diodes with any other thermally activated over current protection device.

In some embodiments, the barrier metal and Zener (TVS) diode technology can be used in an integrated TVS and fuse to extend device cycle life. In some embodiments, a diffusion barrier on the TVS or Zener can be used to prevent fuse generated heating and cycling from driving aluminum to junction diffusion, generating premature or cycle dependent diode shorting that would occur with a tradition aluminum silicon structure. In some embodiments, thermally generated second breakdown can be used to crowbar the fuse in the event that it heats the diode beyond the design specific the secondary breakdown temperature.

In some embodiments, the thermally dependent second breakdown at the secondary breakdown temperature can be leveraged and controlled to support improved crowbar functionality for fuses that exceed the secondary breakdown temperature. In some embodiments, the crowbar event temperature can be controlled for integrated fuse/TVS diodes via a thermal secondary breakdown mechanism, versus aluminum migration. In some embodiments, the secondary breakdown temperature can be controlled by doping concentrations to control max steady state temperature the integrated device will support before the diode crowbars the fuse. In some embodiments, second breakdown and higher the secondary breakdown temperature (via increased doping concentrations) can be used to extend the peak temperature before crowbar to extend the power rating of the diode in a fuse integrated solution. In some embodiments, second breakdown and a lower the secondary breakdown temperature (via lower doping concentrations) can be used to increase the thermal protection function of the diode and reduce the temperature at which it crowbars the fuse.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. An apparatus, comprising:
a barrier diode including a refractory metal layer coupled to a semiconductor substrate including at least a portion of a PN junction; and
an overcurrent protection device operably coupled to the barrier diode.

2. The apparatus of claim 1, wherein the overcurrent protection device is a polymeric positive temperature coefficient device.

3. The apparatus of claim 1, wherein the overcurrent protection device is a polymeric positive temperature coefficient device integrated into a single, discrete component with the barrier diode.

4. The apparatus of claim 1, wherein the overcurrent protection portion is a polymeric positive temperature coefficient device, the polymeric positive temperature coefficient device is thermally coupled to the barrier diode such that heat produced by the barrier diode is transferred to the polymeric positive temperature coefficient device and causes the polymeric positive temperature coefficient device to change from a low resistance state to a high resistance state.

5. The apparatus of claim 1, wherein the refractory metal layer is configured to substantially prevent the barrier diode from failing short in response to diffusion of at least a portion of a conductor into the PN junction at a diffusion breakdown temperature.

6. The apparatus of claim 1, wherein the barrier diode is configured to change between a voltage regulation state and a temperature-induced conduction state.

7. The apparatus of claim 1, further comprising:
a conductor included in the barrier diode as a terminal, the barrier diode configured to reversibly change from a voltage regulation state to a temperature-induced conduction state, the temperature-induced conduction state occurs at a temperature higher than a diffusion breakdown temperature associated with diffusion of at least a portion of the conductor into the PN junction of the barrier diode.

8. The apparatus of claim 1, wherein the overcurrent protection device is a fuse.

9. The apparatus of claim 1, wherein the refractory includes titanium (Ti).

10. The apparatus of claim 1, further comprising:
a conductor included in the barrier diode as a terminal, the barrier diode configured to reversibly change from a voltage regulation state to a temperature-induced conduction state, the temperature-induced conduction state occurs at a temperature higher than a melt temperature of a fuse element of the fuse.

11. The apparatus of claim 1, wherein the refractory metal layer is included in a terminal of the barrier diode.

12. The apparatus of claim 1, wherein the overcurrent protection portion is operably coupled to the barrier diode such that heat produced by the overcurrent protection portion at a current below a rated current of the overcurrent protection portion causes the barrier diode to change from a voltage regulation state to a temperature-induced conduction state.

13. The apparatus of claim 1, wherein the refractory metal layer includes at least one of niobium, molybdenum, tantalum, tungsten, titanium, or rhenium.

14. An apparatus, comprising:
a barrier diode configured to function as a silicon-controlled rectifier circuit, the barrier diode including a refractory metal layer coupled to a semiconductor substrate having a PN junction, the refractory metal layer and the semiconductor substrate define an interface parallel to the PN junction; and
a barrier diode configured to change, in response to a temperature of the barrier diode exceeding a secondary breakdown temperature, from an off-state to an on-state.

15. The apparatus of claim 14, wherein the barrier diode is a two terminal device including a first terminal and a second terminal, the refractory metal layer is included in the first terminal.

16. The apparatus of claim 14, wherein the barrier diode is configured to exceed the threshold temperature in response to a first portion of heat, the silicon-controlled rectifier includes a heat sink coupled to the metal layer and configured receive a second portion of the heat.

17. The apparatus of claim 14, wherein the barrier diode is configured to remain at a temperature above the secondary breakdown temperature in response to heat caused by a current.

18. A method, comprising:
receiving a first current at a barrier diode including a refractory metal layer coupled to a semiconductor substrate having a PN junction while the barrier diode is in the voltage regulation state; and
receiving heat at the barrier diode until the barrier diode changes from a voltage regulation state to a temperature-induced conduction state in response to a temperature of the barrier diode increasing beyond a secondary breakdown temperature.

19. The method of claim 18, wherein the barrier diode is configured to change from the voltage regulation state to the temperature-induced conduction state while a voltage across the barrier diode is below a threshold breakdown voltage associated with the voltage regulation state.

20. The method of claim 18, wherein the first current is a leakage current,
the method further comprising:
receiving a second current greater than the first current at the barrier diode in response to the barrier diode changing to the temperature-induced conduction state.

21. An apparatus, comprising:
a barrier diode including a barrier layer coupled to a semiconductor substrate including at least a portion of a PN junction, the barrier diode configured to reversibly change from a temperature-induced conduction state to a voltage regulation state after absorbing a plurality of power pulses that each cause the temperature of the PN junction to exceed the diffusion breakdown temperature.

22. The apparatus of claim 21, wherein the temperature is below the secondary breakdown temperature.

23. The apparatus of claim 21, wherein the diffusion breakdown temperature is approximately between 300° C. to 400° C.

24. The apparatus of claim 21, wherein the diffusion breakdown temperature is referenced to an aluminum metal coupled to a PN junction.

25. The apparatus of claim 21, wherein the temperature is above the secondary breakdown temperature.

26. The apparatus of claim 21, wherein the barrier diode is configured to absorb each of the plurality of power pulses without failing short.

27. The apparatus of claim 21, wherein the barrier layer is included in a terminal of the barrier diode.

28. The apparatus of claim 21, wherein the barrier diode is configured to have a breakdown voltage versus temperature behavior that tapers at a temperature lower than the second breakdown temperature.
